(19) United States
(12) Patent Application Publication
(10) Pub. No.: US 2025/0130495 A1
(43) Pub. Date: Apr. 24, 2025

(54) POLYBENZOXAZOL PRECURSOR OR POLYIMIDE PRECURSOR OR THE COPOLYMER THEREOF, AND POSITIVE PHOTOSENSITIVE RESIN COMPOSITION THEREFROM

(71) Applicant: DUK SAN NEOLUX CO., LTD., Cheonan-si (KR)

(72) Inventors: Gwang Sik SONG, Cheonan-si (KR); Yeon Joon CHUNG, Cheonan-si (KR); Changmin LEE, Cheonan-si (KR); Kyung Soo KIM, Cheonan-si (KR)

(73) Assignee: DUK SAN NEOLUX CO., LTD., Cheonan-si (KR)

(21) Appl. No.: 18/922,303

(22) Filed: Oct. 21, 2024

(30) Foreign Application Priority Data
Oct. 20, 2023 (KR) 10-2023-0141114

(51) Int. Cl. G03F 7/039; C08G 73/22; G03F 7/004

(52) U.S. Cl. CPC G03F 7/039; C08G 73/22; G03F 7/0045; C08G 2150/00

(57) ABSTRACT

Provided is a photosensitive resin composition using a polyimide precursor and a benzoxazol precursor copolymer resin that does not contain fluorine, which exhibits a degree of pattern implementation similar to those of existing fluorine-based photosensitive compositions and has the effect of leaving less residues after development.

### TECHNICAL FIELD

The present disclosure relates to a polybenzoxazol precursor or polyimide precursor, a copolymer thereof, and a positive-type photosensitive resin composition, which is used for a semiconductor device or display device prepared using the same.

### BACKGROUND

A photolithography process largely proceeds in order of a coating step, in which a photoresist composition is applied onto a substrate; an exposure step, in which a pattern is formed on a photoresist layer using a light source, E-beam, etc. that has passed through a mask; and a development step, in which specific areas of the patterned photoresist layer are removed; and the process is performed by adding a heat treatment (baking) step to remove the solvent from the photoresist composition or to harden the film in the middle of each step.

The photolithography process may largely be divided into negative and positive processes, and specifically, be divided into a positive process in which, in the development step, the exposed part reacts chemically with a developer and the reaction product is dissolved and removed, and a negative process in which, conversely, the non-exposed area reacts chemically with a developer, and the reaction product is dissolved and removed. Between them, in the positive process, a photoactive compound, which absorbs light during the exposure step and increases its solubility is used to allow for the precise removal of only the exposed area during the development step, thereby obtaining a more precise and more accurate pattern compared to the negative process.

As the positive photosensitive resin composition, which is used in a conventional semiconductor device or display device, the resins of polyimide, polybenzoxazole, etc., have been used due to their high heat resistance, chemical resistance, and weather resistance, etc., but with a progress of research on environmental pollution and toxicity of halogenated compounds (which are mainly used as materials) to humans, there is a growing demand for new materials to replace the halogenated compounds.

### PRIOR ART DOCUMENT

### Patent Document

(Patent Document 1) KR Patent Application Publication No. 10-2010-0080344

### SUMMARY

In order to solve the problems of the related art, the present disclosure provides a precursor and a copolymer, which is synthesized by introducing a monomer, which does not contain a halogen atom, into a polybenzoxazol precursor or polyimide precursor.

Additionally, the present disclosure provides a positive photosensitive resin composition using the polybenzoxazol precursor or polyimide precursor and a copolymer resin.

Additionally, the present disclosure provides a pattern or film formed by the positive photosensitive composition, and a semiconductor device or display device prepared using the same.

It is preferable that the benzoxazol precursor or polyimide precursor and copolymer include a repeating unit selected from the group consisting of the following Formulas 1-1 and 1-2, and a combination thereof.

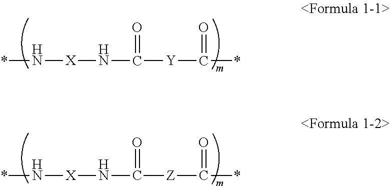

wherein in Formulas 1-1 and Formula 1-2 above,
1) * represents a part where a bond is connected by a repeating unit,
2) X is Formula 2 below:

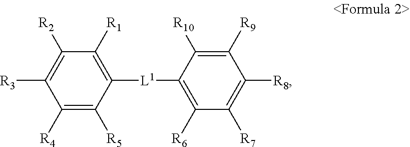

3) two of R¹ to R¹⁰ are connection parts with an amide group of Formula 1-1 or Formula 1-2 above,
4) the remaining ones of R¹ to R¹⁰ excluding the connection parts are each independently selected from the group consisting of hydrogen; deuterium; a hydroxy group; a C₆₋₃₀ aryl group; a C₂₋₃₀ heterocyclic group comprising at least one heteroatom among O, N, S, Si, and P; a fused ring group of a C₆₋₃₀ aliphatic ring and a C₆₋₃₀ aromatic ring; a C₁-₂₀ alkyl group; a C₂-C₀ alkenyl group; a C₂-₂₀ alkynyl group; a C₁-₂₀ alkoxy group; a C₆-₃₀ aryloxy group; a fluorenyl group; a carbonyl group; an ether group; a carboxyl group; a C₁-₂₀ alkoxycarbonyl group; and a combination thereof,
5) L¹ is selected from the group consisting of a single bond; a C₆-₃₀ arylene group; a C₂₋₃₀ heterocyclic group comprising at least one heteroatom among O, N, S, Si, and P; a fused ring group of a C₆₋₃₀ aliphatic ring and a C₆₋₃₀ aromatic ring; a C₁-₂₀ alkylene group; a C₃₋₂₀ cycloalkylene group; a C₂-₂₀ alkenylene group; a C₃₋₂₀ cycloalkenylene group; a C₂₋₂₀ alknylene group; a C₃₋₂₀ cycloalkynylene group; and —O—, —S—, —SO₂—, Si(CH₃)₂—, —C(SiCH₃)₂, —C₆H₄—, —CO—, —NHCO—, and —COO—,
6) when L¹ is a single bond, neighboring R₁ and R₁₀; and R₅ and R₆, which are not the connection parts, can form a ring,
7) Y and Z are each independently selected from the group consisting of a C₆-₃₀ arylene group; a C₂₋₃₀ heterocyclic group comprising at least one heteroatom among O, N, S, Si, and P; a fused ring group of a C₆₋₃₀ aliphatic ring and a C₆₋₃₀ aromatic ring; a C₁-₂₀ alkylene group; a C₃₋₂₀ cycloalkylene group; a C₂-₂₀ alkenylene group; a C₃₋₂₀ cycloalkenylene group; a C₂₋₂₀ alknylene group; a C₃₋₂₀ cycloalkynylene group; and a combination thereof,
8) in Y or Z, each independently, at least one carboxylic acid group; or an ester group having an end of C₁-₂₀ can be additionally substituted,
9) m or n is an integer of 1 or more, and
10) the polymer end is connected by one selected from Formulas Q-1 to Q-10 below.

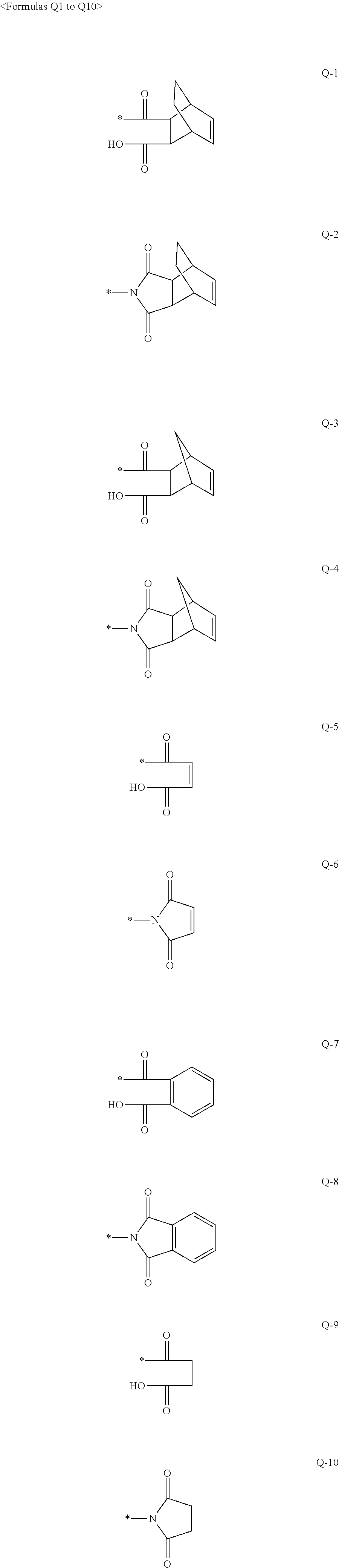

It is preferable that Formula 2 above be represented as A-1 to A-15 below.

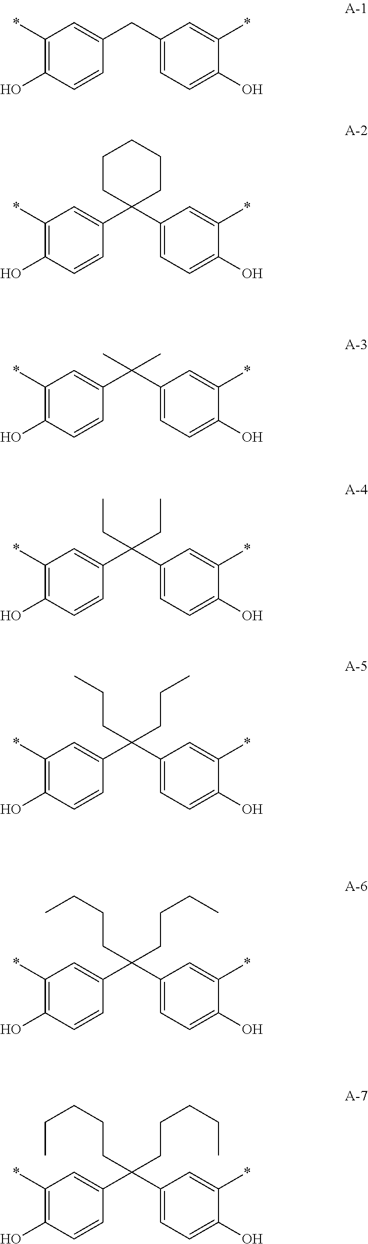

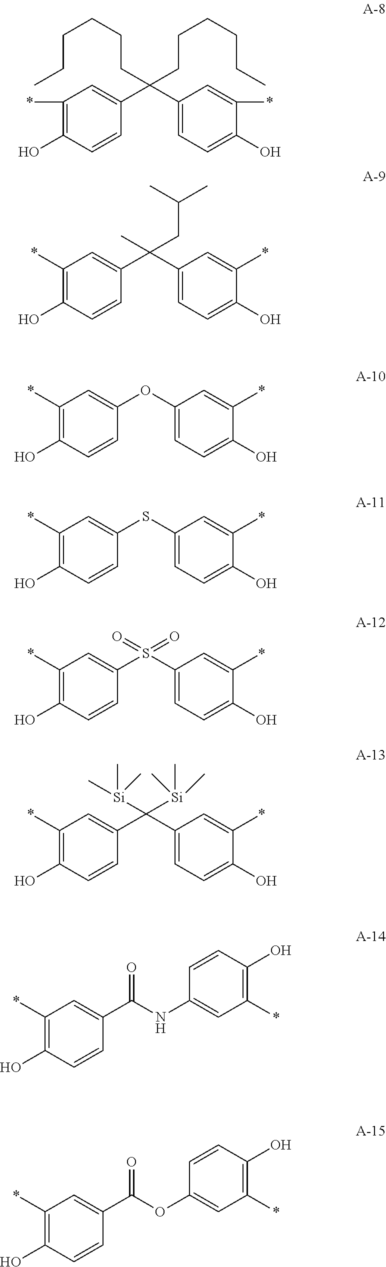

In A-1 to A-15 above, * represents a connection part with an amide group of Formula 1-1 or Formula 1-2 above.

In addition, it is preferable that Formula 2 above be represented as B-1 to B-15 below.

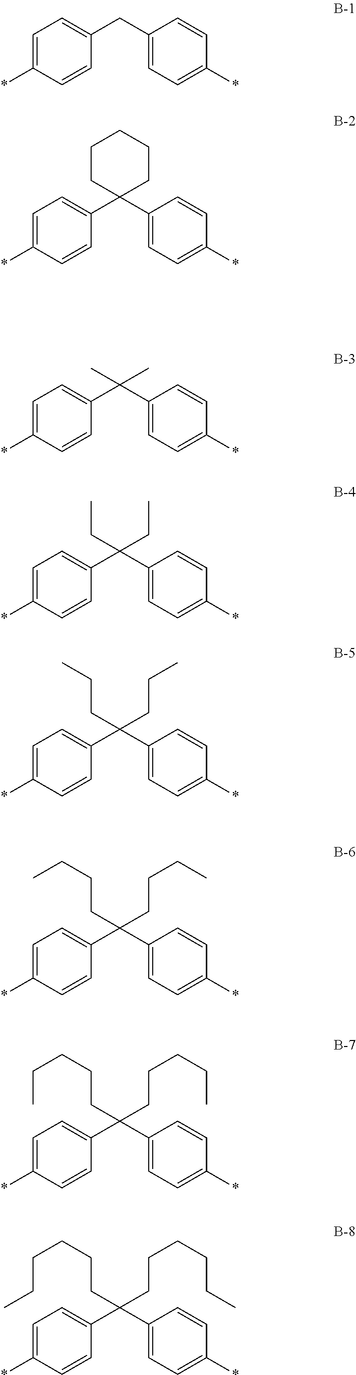

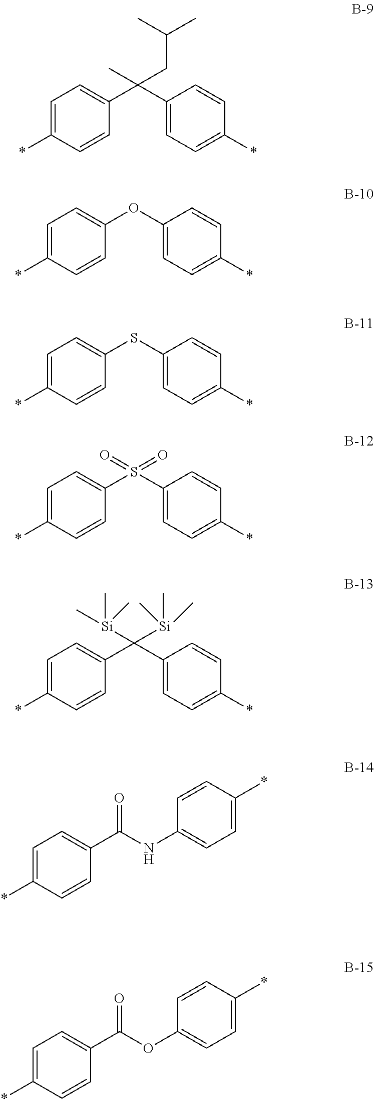

In B-1 to B-15 above, * represents a connection part with an amide group of Formula 1-1 or Formula 1-2 above.

It is preferable that the benzoxazole copolymer be prepared from a diamine monomer; a diacylchloride monomer; a dianhydride monomer; and an anhydride monomer.

It is preferable that the diamine include at least one monomer selected from the group consisting of 4,4′-methylenebis[2-aminophenol], 2,2-bis(3-amino-4-hydroxyphenyl)propane, 3,3-bis(3-amino-4-hydroxyphenyl)pentane, 4,4-bis(3-amino-4-hydroxyphenyl)heptane, 5,5-bis(3-amino-4-hydroxyphenyl)nonane, 6,6-bis(3-amino-4-hydroxyphenyl)dodecane, 7,7-bis(3-amino-4-hydroxyphenyl)tridecane, 4,4′-cyclohexylidinebis[2-aminophenol] 4,4′-(1,3-dimethylbutylidine)bis[2-aminophenol], 4,4′-oxybis[2-aminophenol], 4,4′-thiobis[2-aminophenol], bis(3-amino-4-hydroxyphenyl)sulfone, 4,4′-(bis(trimethylsilyl)methylene)bis(2-aminophenol), 4-hydroxy-N-(4-hydroxy-3λ³-phenyl)3-λ³benzamide, 4,4-diaminodiphenylmethane, 4,4′-(1-methyleneethylidine)bis[benzeneamine], 4,4′-(1-ethylpropylidine)bis[benzeneamine], 4,4′-(1-propylbutyridine)bis[benzeneamine], 4,4′-(1-butylpentylidene)bis[benzeneamine], 4,4′-(1-pentylhexylidine)bis[benzeneamine], 4,4′-(hexylheptylidine)bis[benzeneamine], 4,4′-cyclohexylidinebis[benzeneamine], 4,4′-(1,3-dimethylbutylidine)bis[benzeneamine], 4,4′-diaminodiphenyl ether, 4,4′-diaminodiphenyl sulfide, 4,4′-sulfonyldianiline, 4,4′-(bis(trimethylsilyl)methylidine)dianiline, 4-amino-N-(4-aminophenyl)benzoamide, 4-aminophenyl 4-aminobenzoate, and a combination thereof.

It is preferable that the diacylchloride include at least one monomer selected from the group consisting of 4,4′-oxybisbenzoyl chloride, 1,2-cyclobutanedicarboxylic acid dichloride, terephthaloyl chloride, isophthaloyl chloride, 4,4′-biphenyldicarbonyl chloride, 1,4-naphthalenedicarbonyl chloride, 4,4′-sulfonyldibenzoyl chloride, 1,4-cyclohexanedicarboxylic acid dichloride, and a combination thereof.

It is preferable that the dianhydride include at least one monomer selected from the group consisting of 4,4-oxydiphthalic anhydride, 3,3′,4,4′-biphenyltetracarboxylic dianhydride, 2,3,3′4′-biphenyltetracarboxylic acid dianhydride, bicyclo[2,2,2]octa-7-en-2,3,5,6-tetracarboxylic acid dianhydride, 4,4′-(hexafluoroisopropylidine)diphthalic anhydride, bicyclo[2,2,2]octan-2,3,5,6-tetracarboxylic dianhydride, 3,3′,4,4′-benzophenonetetracarboxylic acid dianhydride, 1,2,3,4-butanetetracarboxylic acid dianhydride, cyclobutan-1,2,3,4-tetracarboxylic acid dianhydride, cyclocyclohexan-1,2,4,5-tetracarboxylic acid dianhydride, dicyclohexyl-3,4,3′4′-tetracarboxylic acid dianhydride, 1,4,5,8-naphthalenetetracarboxylic acid dianhydride, bicyclooctanetetracarboxyldianhydride, and a combination thereof.

It is preferable that the anhydride include at least one monomer selected from the group consisting of bicyclo[2.2.2]octa-5-en-2,3-dicarboxylic anhydride, 5-norbornen-2,3-dicarboxylic anhydride, maleic anhydride, phthalic anhydride, succinic anhydride, and a combination thereof.

It is preferable that the weight average molecular weight of the copolymer be 5,000 g/mol to 40,000 g/mol.

In a specific embodiment of the present disclosure, it is preferable that the positive photosensitive resin composition according to the present disclosure include a benzoxazole copolymer; a photoactive compound; a solvent; and an additive.

It is preferable that the photoactive compound include at least one of Formulas P-1 to P-8 below.

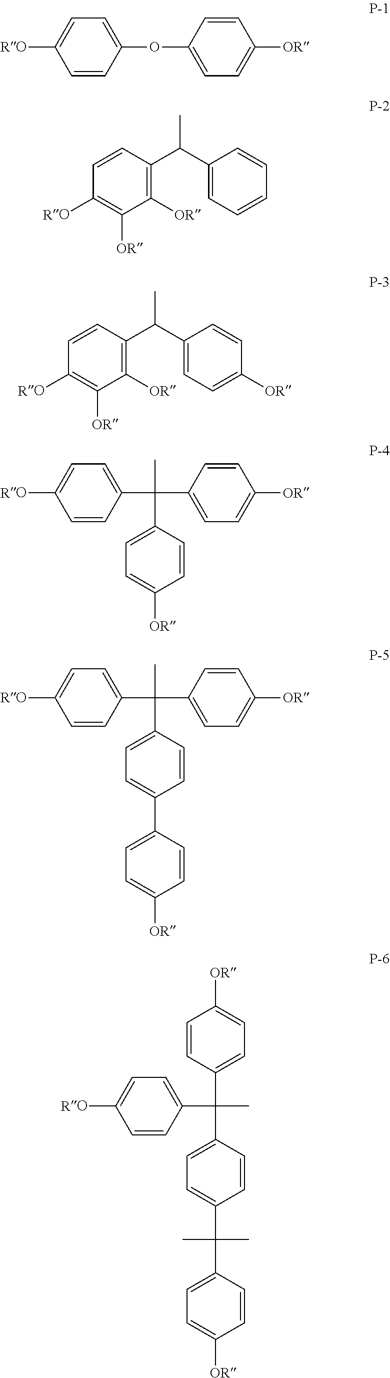

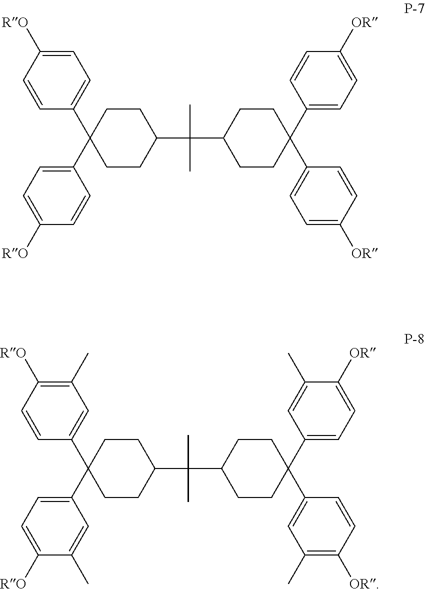

In P-1 to P-8 above, R″s are each independently hydrogen; Formula S-1 below; or Formula S-2 below.

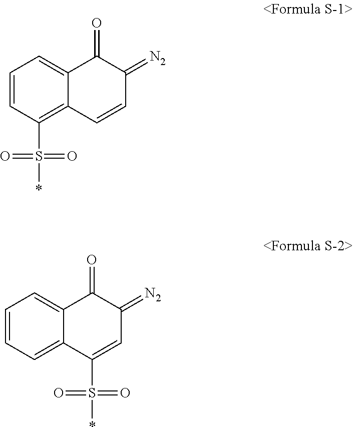

It is preferable that the solvent include at least one selected from the group consisting of N,N-dimethylformamide, N-methylformanilide, N-methylacetamide, N,N-dimethylacetamide, N-methylpyrrolidone, dimethyl sulfoxide, benzyl ethyl ether, dihexyl ether, acetyl acetone, gamma-butyrolactone, diethylene glycol monomethyl ether, diethylene glycol monoethyl ether, diethylene glycol dimethyl ether, diethylene glycol methyl ethyl ether, diethylene glycol diethyl ether, propylene glycol methyl ether acetate, propylene glycol propyl ether acetate, and a combination thereof.

It is preferable that the additive include at least one selected from the group consisting of a silane-based coupling agent; a surface leveling agent; a surfactant; a crosslinking agent; and a combination thereof.

It is preferable that the benzoxazole copolymer be contained in an amount of 5 wt % to 50 wt % based on the total amount of the composition.

It is preferable that the photoactive compound be contained in an amount of 1 wt % to 50 wt % based on the total amount of the composition.

It is preferable that the solvent be contained in an amount of 50 wt % to 95 wt % based on the total amount of the composition.

It is preferable that the additive be contained in an amount of 0.001 wt % to 10 wt % based on the total amount of the composition.

In a specific embodiment of the present disclosure, it is preferable that a pattern or film prepared from the positive photosensitive resin composition be provided.

In a specific embodiment of the present disclosure, it is preferable that a semiconductor device or display device prepared using the pattern or film be provided.

In a specific embodiment of the present disclosure, it is preferable that an electronic device which includes the semiconductor device or display device and a control unit for driving the same be provided.

### Advantageous Effects

According to the present disclosure, there is provided a photosensitive resin composition that does not contain a halogen compound by introducing a halogen-free monomer into the components of polybenzoxazole and polyimide precursor and copolymer resin, which may be used in the manufacture of a display device or semiconductor device.

### DETAILED DESCRIPTION

When it is determined that a detailed description of a related known constitution or function may obscure the gist of the present disclosure in describing the present disclosure, the detailed description thereof may be omitted. When the expressions “includes”, “has”, “consisting of”, etc. mentioned in this specification are used, other parts may be added unless “only” is used. When a component is expressed in the singular form, it may include a case in which the plural form is included unless otherwise explicitly stated.

In addition, in describing the components of the present disclosure, terms such as first, second, A, B, (a), (b), etc. may be used. Such terms are only for distinguishing the components from other components, and the essence, order, sequence, number, or etc. of the relevant components are not limited by the terms.

In the description of the positional relationship of the components, when two or more components are described as being “connected”, “linked”, or “fused”, etc., the two or more components may be directly “connected”, “linked”, or “fused”, but it should be understood that the two or more components may also be “connected”, “linked”, or “fused” by way of a further “interposition” of a different component. Here, the different component may be included in any one or more of the two or more components that are to be “connected”, “linked”, or “fused” to each other.

In addition, when a component such as a layer, a film, a region, a plate, or etc. is described to be “on top” or “on” of another component, it should be understood that this may not only include a case where the component is “immediately on top of” another component, but also include a case where another component is disposed therebetween. In contrast, it should be understood that when a component is described to be “immediately on top of” another part, this may mean that there is not another part disposed therebetween.

In the description of the temporal flow relationship relating to the components, the operation method, or the preparation method, for example, when the temporal precedence or flow precedence is described by way of “after”, “subsequently”, “thereafter”, “before”, etc., it may also include cases where the flow is not continuous unless terms such as “immediately” or “directly” are used.

Meanwhile, when the reference is made to numerical values or corresponding information for components, numerical values or corresponding information may be interpreted as including an error range that may occur due to various factors (e.g., process factors, internal or external shocks, noise, etc.) even if a separate explicit description is not present.

The terms used in this specification and the appended claims should not be construed as limited to their usual or dictionary meanings, but should be interpreted in a way that is consistent with the technical spirit of the present disclosure, based on the principle that the inventor may appropriately define the concept of a term in order to best describe his or her invention.

As used herein, the term “halo” or “halogen” includes fluorine (F), chlorine (Cl), bromine (Br), and iodine (I), unless otherwise specified.

As used herein, the term “alkyl” or “alkyl group” has 1 to 60 carbons linked by a single bond unless otherwise specified, and refers to a radical of a saturated aliphatic functional group, including a linear chain alkyl group, a branched chain alkyl group, a cycloalkyl (alicyclic) group, an alkyl-substituted cycloalkyl group, and a cycloalkyl-substituted alkyl group.

As used herein, the term “haloalkyl group” or “halogenalkyl group” refers to an alkyl group in which a halogen is substituted, unless otherwise specified.

As used herein, the term “alkenyl” or “alkynyl” has a double bond or a triple bond, respectively, includes a linear or branched chain group, and has 2 to 60 carbon atoms, unless otherwise specified, but is not limited thereto.

As used herein, the term “cycloalkyl” refers to an alkyl which forms a ring having 3 to 60 carbon atoms unless otherwise specified, but is not limited thereto.

As used herein, the term “an alkoxy group” or “alkyloxy group” refers to an alkyl group to which an oxygen radical is linked, and has 1 to 60 carbon atoms unless otherwise specified, but is not limited thereto.

As used herein, the term “alkenoxyl group”, “alkenoxy group”, “alkenyloxyl group”, or “alkenyloxy group” refers to an alkenyl group to which an oxygen radical is linked, and has 2 to 60 carbon atoms unless otherwise specified, but is not limited thereto.

As used herein, the terms “aryl group” and “arylene group” each have 6 to 60 carbon atoms unless otherwise specified, but are not limited thereto. As used herein, the aryl group or arylene group includes monocyclic compounds, ring assemblies, multiple fused cyclic compounds, etc. For example, the aryl group may include a phenyl group, a monovalent functional group of biphenyl, a monovalent functional group of naphthalene, a fluorenyl group, and a substituted fluorenyl group, and the arylene group may include a fluorenylene group and a substituted fluorenylene group.

As used herein, the term “ring assemblies” means that two or more ring systems (monocyclic or fused ring systems) are directly connected to each other through a single bond or double bond, and the number of direct links between such rings is one less than the total number of ring systems contained in the compound. In the ring assemblies, the same or different ring systems may be directly connected to each other through a single bond or double bond.

As used herein, since the aryl group includes ring assemblies, the aryl group includes biphenyl and terphenyl in which a benzene ring, which is a single aromatic ring, is connected by a single bond. In addition, since the aryl group also includes a compound in which an aromatic ring system fused to a single aromatic ring is connected by a single bond, it also includes, for example, a compound in which a benzene ring (which is a single aromatic ring) and fluorine (which is a fused aromatic ring system) are linked by a single bond.

As used herein, the term “multiple fused ring system” refers to a fused ring form in which at least two atoms are shared, and it includes a form in which ring systems of two or more hydrocarbons are fused, a form in which at least one heterocyclic system including at least one heteroatom is fused, etc. Such a multiple fused ring system may be an aromatic ring, a heteroaromatic ring, an aliphatic ring, or a combination of these rings. For example, in the case of an aryl group, it may be a naphthalenyl group, a phenanthrenyl group, a fluorenyl group, etc., but is not limited thereto.

As used herein, the term “a spiro compound” has “a spiro union”, and the spiro union refers to a linkage in which two rings are formed by sharing only one atom. At this time, the atom shared by the two rings is called a “spiro atom”, and they are each called “monospiro-”, “dispiro-”, and “trispiro-” compounds depending on the number of spiro atoms included in a compound.

As used herein, the terms “fluorenyl group”, “fluorenylene group”, and “fluorenetriyl group” refer to a monovalent, divalent, or trivalent functional group in which R, R′, R″, and R′″ are all hydrogen in the following structures, respectively, unless otherwise specified; “substituted fluorenyl group”, “substituted fluorenylene group”, or “substituted fluorenetriyl group” means that at least one of the substituents R, R′, R″, and R′″ is a substituent other than hydrogen, and include cases where R and R′ are bound to each other to form a spiro compound together with the carbon to which they are linked. As used herein, all of the fluorenyl group, the fluorenylene group, and the fluorenetriyl group may also be referred to as a fluorene group regardless of valences such as monovalent, divalent, trivalent, etc.

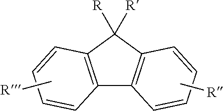

In addition, R, R′, R″, and R′″ may each independently be an alkyl group having 1 to 20 carbon atoms, an alkenyl group having 1 to 20 carbon atoms, an aryl group having 6 to 30 carbon atoms, and a heterocyclic group having 2 to 30 carbon atoms and, for example, the aryl group may be phenyl, biphenyl, naphthalene, anthracene, or phenanthrene, and the heterocyclic group may be pyrrole, furan, thiophene, pyrazole, imidazole, triazole, pyridine, pyrimidine, pyridazine, pyrazine, triazine, indole, benzofuran, quinazoline, or quinoxaline. For example, the substituted fluorenyl group and the fluorenylene group may each be a monovalent functional group or divalent functional group of 9,9-dimethylfluorene, 9,9-diphenylfluorene, and 9,9′-spirobi[9H-fluorene].

As used herein, the term “heterocyclic group” includes not only an aromatic ring such as “heteroaryl group” or “heteroarylene group”, but also a non-aromatic ring, and refers to a ring having 2 to 60 carbon atoms each including one or more heteroatoms unless otherwise specified, but is not limited thereto. The term used in this application “heteroatom” refers to N, O, S, P, or Si unless otherwise specified, and a heterocyclic group refers to a monocyclic group including a heteroatom, ring assemblies, multiple fused ring systems, spiro compounds, etc.

For example, the “heterocyclic group” may include a compound including a heteroatom group (e.g., SO₂, P═O, etc.), such as the compound shown below, instead of carbon that forms a ring.

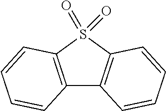 [SMILES: O=S1(=O)c2ccccc2-c2ccccc21]

As used herein, the term “ring” includes monocyclic and polycyclic rings, and includes heterocycles containing at least one heteroatom as well as hydrocarbon rings, and includes aromatic and non-aromatic rings.

As used herein, the term “polycyclic” includes ring assemblies (e.g., biphenyl, terphenyl, etc.), fused multiple ring systems, and spiro compounds, includes non-aromatic as well as aromatic compounds, and includes heterocycles containing at least one heteroatom as well as hydrocarbon rings.

As used herein, the term “alicyclic group” refers to cyclic hydrocarbons other than aromatic hydrocarbons, and it includes monocyclic, ring assemblies, fused multiple ring systems, spiro compounds, etc., and refers to a ring having 3 to 60 carbon atoms unless otherwise specified, but is not limited thereto. For example, when benzene (i.e., an aromatic ring) and cyclohexane (i.e., a non-aromatic ring) are fused, it also corresponds to an aliphatic ring.

Additionally, when prefixes are named consecutively, it means that the substituents are listed in the order they are described. For example, in the case of an arylalkoxy group, it means an alkoxy group substituted with an aryl group; in the case of an alkoxycarbonyl group, it means a carbonyl group substituted with an alkoxy group; additionally, in the case of an arylcarbonyl alkenyl group, it means an alkenyl group substituted with an arylcarbonyl group, in which the arylcarbonyl group is a carbonyl group substituted with an aryl group.

Additionally, unless otherwise specified, the term “substituted” in the expression “substituted or unsubstituted” as used herein refers to a substitution with one or more substituents selected from the group consisting of deuterium, a halogen, an amino group, a nitrile group, a nitro group, a C₁-₃₀ alkyl group, a C₁-₃₀ alkoxy group, a C₁-₃₀ alkylamine group, a C₁-₃₀ alkylthiophene group, a C₆-₃₀ arylthiophene group, a C₂-₃₀ alkenyl group, a C₂-₃₀ alkynyl group, a C₃-₃₀ cycloalkyl group, a C₆-₃₀ aryl group, a C₆-₃₀ aryl group substituted with deuterium, a C₈-₃₀ arylalkenyl group, a silane group, a boron group, a germanium group, and a C₂₋₃₀ heterocyclic group containing at least one heteroatom selected from the group consisting of O, N, S, Si, and P, but is not limited to these substituents.

As used herein, the “names of functional groups” corresponding to the aryl group, arylene group, heterocyclic group, etc. exemplified as examples of each symbol and a substituent thereof may be described as “a name of the functional group reflecting its valence”, and may also be described as the “name of its parent compound”. For example, in the case of “phenanthrene”, which is a type of an aryl group, the names of the groups may be described such that the monovalent group as “phenanthryl (group)”, and the divalent group as “phenanthrylene (group)”, etc., but may also be described as “phenanthrene”, which is the name of its parent compound, regardless of its valence.

Similarly, in the case of pyrimidine as well, it may be described as “pyrimidine” regardless of its valence, or it may also be described as the “name of the group” of the relevant valence such as pyrimidinyl (group) in the case of monovalent and pyrimidinylene (group) in the case of divalent. Therefore, when the type of a substituent in this application is described as the name of its parent compound, it may refer to an n-valent “group” formed by detachment of a hydrogen atom bonded to a carbon atom and/or hetero atom of its parent compound.

In addition, in describing the names of the compounds or the substituents in the present specification, the numbers, alphabets, etc. indicating positions may be omitted. For example, pyrido[4,3-d]pyrimidine may be described as pyridopyrimidine; benzofuro[2,3-d]pyrimidine as benzofuropyrimidine; 9,9-dimethyl-9H-fluorene as dimethylfluorene, etc. Therefore, both benzo[g]quinoxaline and benzo[f]quinoxaline may be described as benzoquinoxaline.

In addition, unless there is an explicit description, the formulas used in this application are applied in the same manner as in the definition of substituents by the exponent definition of the formula below.

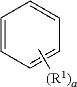

In particular, when a is an integer of 0, it means that the substituent R¹ is absent, that is, when a is 0, it means that all hydrogens are linked to carbons that form a benzene ring, and in this case, the formula or compound may be described while omitting the indication of the hydrogen linked to the carbon. In addition, when a is an integer of 1, one substituent R¹ may be linked to any one of the carbons forming a benzene ring; when a is an integer of 2 or 3, it may be linked, for example, as shown below; even when a is an integer of 4 to 6, it may be linked to the carbon of a benzene ring in a similar manner; and when a is an integer of 2 or greater, R¹ may be the same as or different from each other.

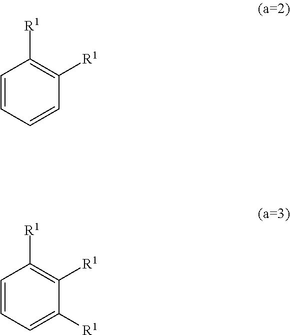

Unless otherwise specified in the present application, forming a ring means that neighboring groups bind to one another to form a single ring or fused multiple ring, and the single ring and the formed fused multiple ring include a heterocycle containing at least one heteroatom as well as a hydrocarbon ring, and may include aromatic and non-aromatic rings.

In addition, unless otherwise specified in the present specification, when indicating a condensed ring, the number in “number-condensed ring” indicates the number of rings to be condensed. For example, a form in which three rings are condensed with one another (e.g., anthracene, phenanthrene, benzoquinazoline, etc.) may be expressed as a 3-condensed ring.

Meanwhile, as used herein, the term “bridged bicyclic compound” refers to a compound in which two rings share 3 or more atoms to form a ring unless otherwise specified. At this time, the shared atoms may include carbon or a hetero atom.

Hereinafter, embodiments of the present disclosure will be described in detail. However, these embodiments are provided for illustrative purposes, and the present disclosure is not limited thereby, and the present disclosure is only defined by the scope of the claims to be described later.

The positive photosensitive resin composition according to one embodiment of the present disclosure, which includes a polybenzoxazole precursor, a polyimide precursor, and a copolymer thereof, may be used to prepare an insulating film, a surface protection film, and a redistribution layer of a semiconductor device; and a pixel defining layer (PDL) of a display device.

In preparing the positive photosensitive resin composition according to one embodiment of the present disclosure for application in a semiconductor device or display device, the following additives may be additionally included.

As an additive that may be added according to one embodiment of the present disclosure, a surface leveling agent may be additionally included to make the thickness of the coating film constant when coating the substrate. In order to uniformly coat according to the characteristics of the substrate surface, a surfactant may be additionally included, and in order to control the adhesive strength to the substrate surface, a silane-based coupling agent may be additionally included. A crosslinking agent may be additionally included to strengthen the binding between polymer molecules during the heat treatment step.

The components constituting a positive-type photosensitive resin composition are as follows.

### (1) Polybenzoxazole Precursor, Polyimide Precursor, and Copolymer Resin

The patterning resin according to one embodiment of the present disclosure may include a polybenzoxazole precursor, a polyimide precursor, and a copolymer resin.

The polybenzoxazole precursor, polyimide precursor, and copolymer resin refer to a hydroxyamide copolymer which can be processed into a polybenzoxazole copolymer through chemical or thermal treatment, and a polybenzoxazole copolymer which has undergone chemical or thermal treatment; or a resin which includes an amic acid copolymer which can be processed into a polyimide copolymer and a polyimide copolymer which has undergone chemical or thermal treatment.

The polybenzoxazole precursor, polyimide precursor, and copolymer resin may be contained in an amount of 5 wt % to 50 wt %, preferably 10 wt % to 40 wt %, based on the total amount of the positive-type photosensitive composition.

The polybenzoxazole precursor, polyimide precursor, and copolymer resin may include the copolymers represented by Formula 1-1 and Formula 1-2 below, etc., but are not limited thereto. These may be used alone or in combination of two or more. The weight average molecular weight of the polybenzoxazole precursor, polyimide precursor, and copolymer resin may be 5,000 g/mol to 40,000 g/mol, preferably 5,000 g/mol to 35,000 g/mol, and more preferably 7,000 g/mol to 25,000 g/mol.

It is preferable that the benzoxazole copolymer include a repeating unit selected from the group consisting of Formula 1-1 and Formula 1-2 below, and a combination thereof.

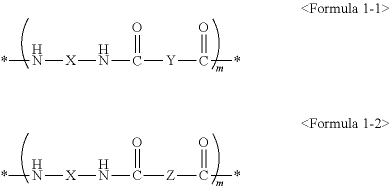

In Formula 1-1 and Formula 1-2 above,
1) * represents a part where a bond is connected by a repeating unit,
2) X is Formula 2 below:

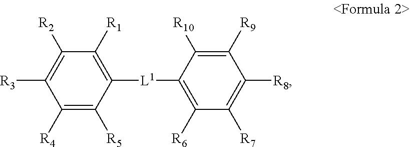

3) two of R¹ to R¹⁰ are connection parts with an amide group of Formula 1-1 or Formula 1-2 above,
4) the remaining ones of R¹ to R¹⁰ excluding the connection parts are each independently selected from the group consisting of hydrogen; deuterium; a hydroxy group; a C₆₋₃₀ aryl group; a C₂₋₃₀ heterocyclic group comprising at least one heteroatom among O, N, S, Si, and P; a fused ring group of a C₆₋₃₀ aliphatic ring and a C₆₋₃₀ aromatic ring; a C₁-₂₀ alkyl group; a C₂-₂₀ alkenyl group; a C₂-₂₀ alkynyl group; a C₁-₂₀ alkoxy group; a C₆-₃₀ aryloxy group; a fluorenyl group; a carbonyl group; an ether group; a carboxyl group; a C₁-₂₀ alkoxycarbonyl group; and a combination thereof,
5) L¹ is selected from the group consisting of a single bond; a C₆-₃₀ arylene group; a C₂₋₃₀ heterocyclic group comprising at least one heteroatom among O, N, S, Si, and P; a fused ring group of a C₆₋₃₀ aliphatic ring and a C₆₋₃₀ aromatic ring; a C₁-₂₀ alkylene group; a C₃₋₂₀ cycloalkylene group; a C₂-₂₀ alkenylene group; a C₃₋₂₀ cycloalkenylene group; a C₂₋₂₀ alknylene group; a C₃₋₂₀ cycloalkynylene group; and —O—, —S—, —SO₂—, Si(CH₃)₂—, —C(SiCH₃)₂, —C₆H₄—, —CO—, —NHCO—, and —COO—,
6) when L¹ is a single bond, neighboring R₁ and R₁₀; and R₅ and R₆, which are not the connection parts, can form a ring,
7) Y and Z are each independently selected from the group consisting of a C₆-₃₀ arylene group; a C₂₋₃₀ heterocyclic group comprising at least one heteroatom among O, N, S, Si, and P; a fused ring group of a C₆₋₃₀ aliphatic ring and a C₆₋₃₀ aromatic ring; a C₁-₂₀ alkylene group; a C₃₋₂₀ cycloalkylene group; a C₂-₂₀ alkenylene group; a C₃₋₂₀ cycloalkenylene group; a C₂₋₂₀ alknylene group; a C₃₋₂₀ cycloalkynylene group; and a combination thereof,
8) in Y or Z, each independently, at least one carboxylic acid group; or an ester group having an end of C₁-₂₀ can be additionally substituted,
9) m or n is an integer of 1 or more, and
10) the polymer end is connected by one selected from Formulas Q-1 to Q-10 below

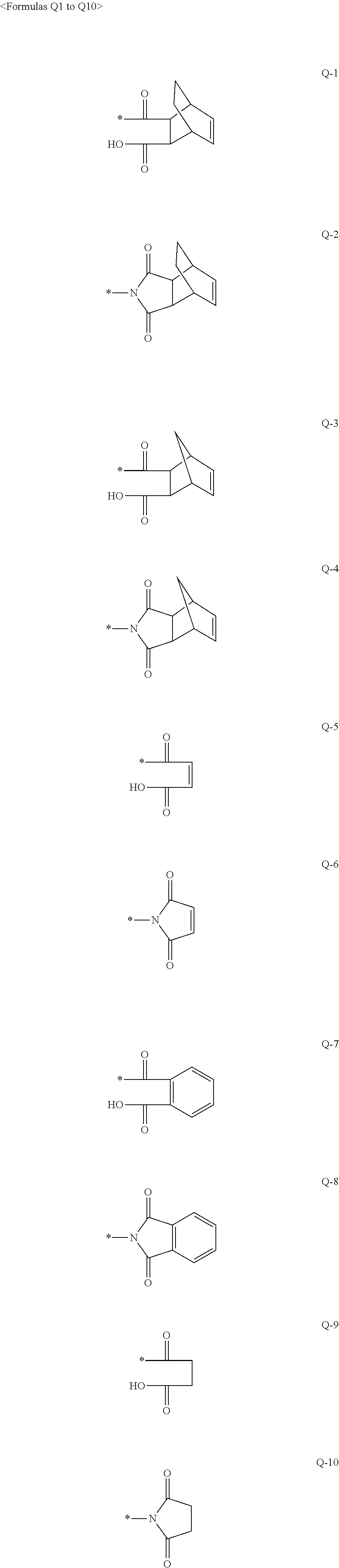

It is preferable that Formula 2 above be represented by A-1 to A-15 below.

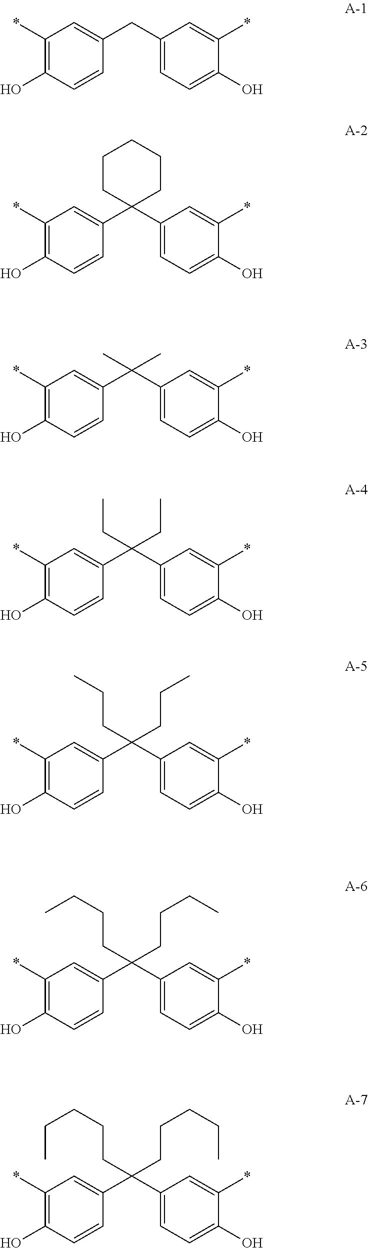

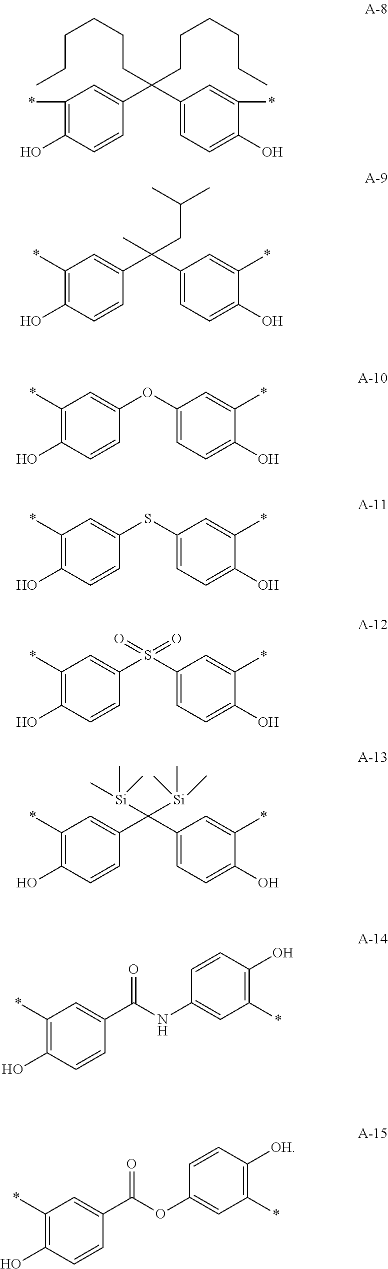

In A-1 to A-15 above, * represents a connection part with an amide group of Formula 1-1 or Formula 1-2 above.

It is preferable that Formula 2 above be represented by B-1 to B-15 below.

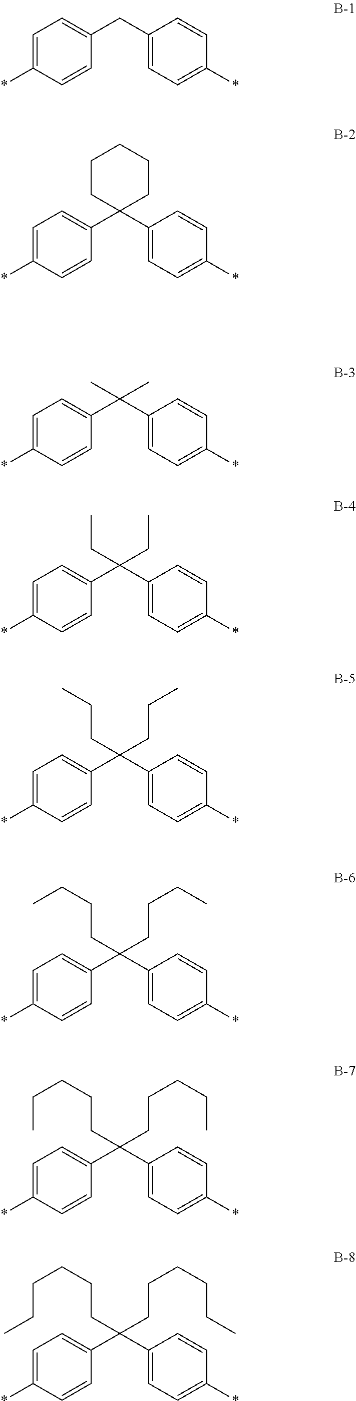

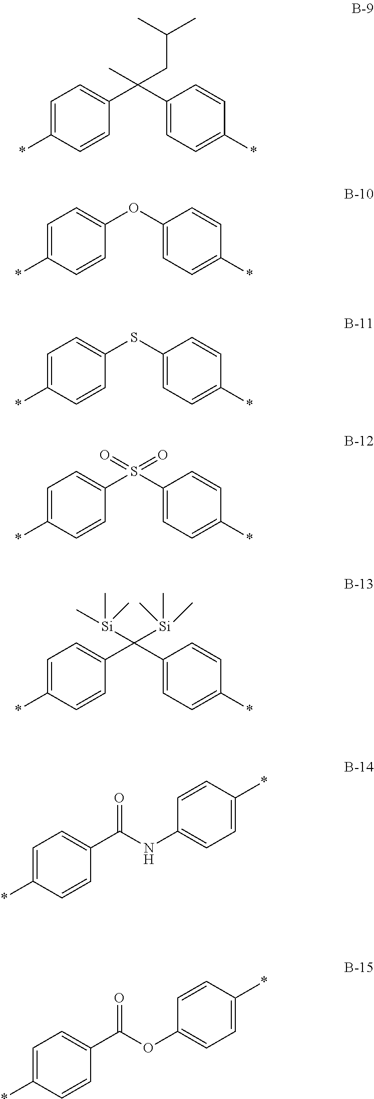

In B-1 to B-15 above, * represents a connection part with an amide group of Formula 1-1 or Formula 1-2 above.

The weight average molecular weight of the polybenzoxazole precursor, polyimide precursor, and copolymer resin may be 5,000 g/mol to 40,000 g/mol, preferably 5,000 g/mol to 35,000 g/mol, and more preferably 7,000 g/mol to 25,000 g/mol. When the weight average molecular weight of the resin is within the above range, no residue of the exposed layer remains during development, and the loss of film thickness of the non-exposed layer is minimized, and thus a good pattern can be obtained. The resin may be contained in an amount of 5 wt % to 50 wt %, and more preferably 15 wt % to 45 wt %, based on the total amount of the photosensitive composition. When the resin is contained within the above range, a constant film thickness can be obtained in the coating step, and excellent sensitivity, developability, and adhesion (an adherent property) can be obtained.

### (2) Photoactive Compound

A photoradical initiator should be used in order to implement a positive pattern with photolithography. As the photoactive compound, an appropriate structure can be selected and used individually or in combination according to the wavelength being used, such as g-line (436 nm), h-line (405 nm), i-line (365 nm), and deep UV (<260 nm).

The photoactive compound is one commonly used in positive photosensitive compositions, for example, a photosensitive diazoquinone compound, and specifically, it may include a phenol compound and sulfonyl-based photosensitive compounds represented by Formula P-1 to Formula P-8 below. Specific examples of R″ include compounds whose structures include hydrogen; deuterium; 1,2-naphthoquinone-2-diazido-5-sulfonic acid or 1,2-naphthoquinone-2-diazido-4-sulfonic acid.

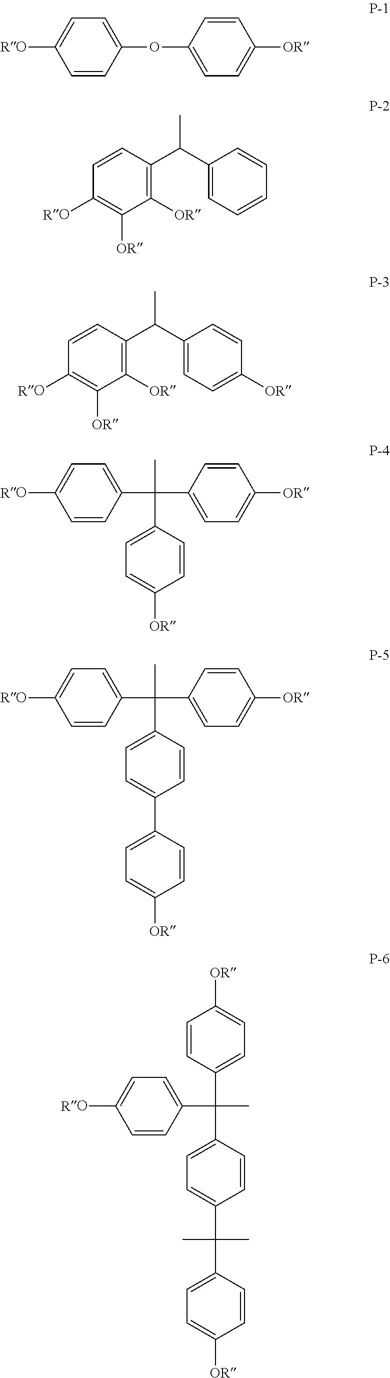

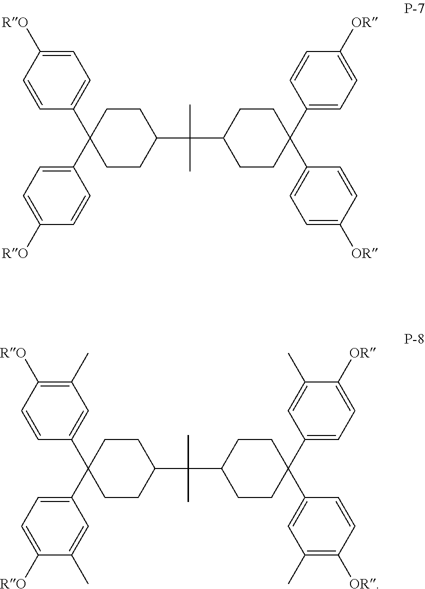

In Formula P-1 to Formula P-8 above, R″ is each independently hydrogen; Formula S-1; or Formula S-2.

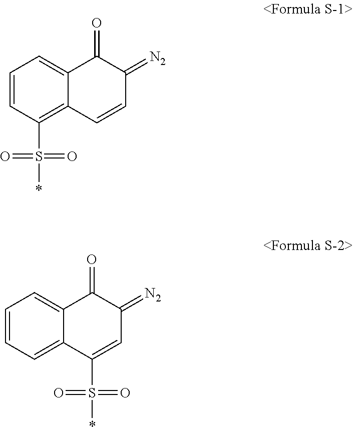

In Formula S-1 and Formula S-2 above, * represents a connection part.

It is preferable that the photoactive compound is contained in an amount of 1 wt % to 50 wt % based on the total amount of the composition.

### (3) Solvent

As the solvent, those materials which are compatible with the benzoxazole copolymer resin, the photoactive compound, and the pigments, but do not react with them may be used.

Examples of the solvent include alcohols such as methanol, ethanol, etc.; ethers such as dichloroethyl ether, n-butyl ether, diisoamyl ether, methylphenyl ether, tetrahydrofuran, etc.; glycol ethers such as ethylene glycol monomethyl ether, ethylene glycol monoethyl ether, etc.; cellosolve acetates such as methyl cellosolve acetate, ethyl cellosolve acetate, diethyl cellosolve acetate, etc.; carbitols such as methylethyl carbitol, diethyl carbitol, diethylene glycol monomethyl ether, diethylene glycol monoethyl ether, diethylene glycol dimethyl ether, diethylene glycol methyl ethyl ether, diethylene glycol diethyl ether, etc.; propylene glycol alkyl ether acetates such as propylene glycol methyl ether acetate, propylene glycol propyl ether acetate, etc.; aromatic hydrocarbons such as toluene, xylene, etc.; ketones such as methyl ethyl ketone, cyclohexanone, 4-hydroxy-4-methyl-2-pentanone, methyl-n-propyl ketone, methyl-n-butyl ketone, methyl-n-amyl ketone, 2-heptanone, etc.; saturated aliphatic monocarboxylic acid alkyl esters such as ethyl acetate, n-butyl acetate, isobutyl acetate, etc.; lactic acid esters such as methyl lactate, ethyl lactate, etc.; oxyacetic acid alkyl esters such as methyl oxyacetate, ethyl oxyacetate, butyl oxyacetate, etc.; alkoxy acetate alkyl esters such as methoxy methyl acetate, methoxy ethyl acetate, methoxy butyl acetate, ethoxy methyl acetate, ethoxy ethyl acetate, etc.; 3-oxypropionic acid alkyl esters such as 3-oxy methyl propionate, 3-oxy ethyl propionate, etc.; 3-alkoxy propionic acid alkyl esters such as 3-methoxy methyl propionate, 3-methoxy ethyl propionate, 3-ethoxy ethyl propionate, 3-ethoxy methyl propionate, etc.; 2-oxypropionic acid alkyl esters such as methyl 2-oxypropionate, ethyl 2-oxypropionate, propyl 2-oxypropionate, etc.; 2-alkoxy propionic acid alkyl esters such as 2-methoxy methyl propionate, 2-methoxy ethyl propionate, 2-ethoxy ethyl propionate, 2-ethoxy methyl propionate, etc.; monooxy monocarboxylic acid alkyl esters of 2-oxy-2-methyl propionic acid esters such as 2-oxy-2-methyl methyl propionate, 2-oxy-2-methyl ethyl propionate, etc., and 2-alkoxy-2-methyl propionic acid alkyls such as 2-methoxy-2-methyl methyl propionate, 2-ethoxy-2-methyl ethyl propionate, etc.; esters such as 2-hydroxyethyl propionate, 2-hydroxy-2-methyl ethyl propionate, ethyl hydroxyacetate, 2-hydroxy-3-methyl methyl butanoate, etc.; and ketonic acid esters such as ethyl pyruvate, etc.

Further, high-boiling point solvents such as N-methylformamide, N,N-dimethylformamide, N-methylformanilide, N-methylacetamide, N,N-dimethylacetamide, N-methylpyrrolidone, dimethyl sulfoxide, benzyl ethyl ether, dihexyl ether, acetylacetone, isophorone, caproic acid, caprylic acid, 1-octanol, 1-nonanol, benzyl alcohol, benzyl acetate, ethyl benzoate, diethyl oxalate, diethyl maleate, γ-butyrolactone, ethylene carbonate, propylene carbonate, and phenyl cellosolve acetate may also be used.

Considering compatibility and reactivity, among the above solvents, glycol ethers such as ethylene glycol monoethyl ether, etc.; ethylene glycol alkyl ether acetates such as ethyl cellosolve acetate, etc.; esters such as ethyl 2-hydroxypropionate, etc.; carbitols such as diethylene glycol monomethyl ether, etc.); and propylene glycol alkyl ether acetates such as propylene glycol methyl ether acetate, propylene glycol propyl ether acetate, etc. may be used.

The solvent may be contained as a balance amount based on the total amount of the photosensitive resin composition, and specifically in an amount of 50 wt % to 95 wt %. When the solvent is contained within the above-described range, the processability when preparing the pattern layer is excellent as the photosensitive resin composition has an appropriate viscosity.

### (4) Other Additives

In order to prevent stains or spots during application, to improve leveling performance, and to prevent the generation of residues due to non-development, the photosensitive resin composition may further include additives, such as malonic acid; 3-amino-1,2-propanediol; a silane-based coupling agent containing a vinyl group or (meth)acryloxy group; a surface leveling agent; a surfactant; a crosslinker; etc.

For example, the photosensitive resin composition may further include a silane-based coupling agent having a reactive substituent such as a vinyl group, a carboxyl group, a methacryloxy group, an isocyanate group, an epoxy group, etc. in order to improve adhesion to a substrate, etc.

Examples of the silane-based coupling agent may include trimethoxysilyl benzoic acid, γ-methacryloxypropyl trimethoxysilane, vinyl triacetoxysilane, vinyl trimethoxysilane, γ-isocyanate propyl triethoxysilane, γ-glycidoxy propyl trimethoxy silane, β-epoxy cyclohexyl ethyl trimethoxy silane, and silane-based coupling agents of Shinetsu Silicon, which are commercially available under the names KBM-502, KBM-602, KBM-573, KBE-9007N, etc., and these may be used alone or in a mixture of two or more.

The silane-based coupling agent may be contained in an amount of 0.01 parts by weight to 10 parts by weight based on 100 parts by weight of the photosensitive resin composition. When the silane-based coupling agent is contained within the above-described range, adhesion, storability, etc. are excellent.

In addition, the photosensitive resin composition may further include a surface leveling agent so as to form a constant film thickness in the coating step, if necessary.

The surface leveling agent to be used may include F-554®, F-556®, F-557®, F-559®, F-560®, F-563®, RS-72-K®, R-40®, R-41®, R-43®, etc. from DIC; Efka® FL3740, Efka® FL3741, Efka® FL3745, Efka® FL3770, etc. from BASF.

The surface leveling agent can be used in an amount of 0.001 to 5 parts by weight per 100 parts by weight of the photosensitive resin composition. When the surface leveling agent is included within the above-described range, coating uniformity can be secured and the film can be coated to have a constant thickness.

In addition, the photosensitive resin composition may further include a surfactant to improve coating properties and prevent defects, if necessary.

The surfactant to be used may include those commercially available under the names of: BM-1000®, BM-1100®, etc. from BM Chemie; Megaface F 142D®, Megaface F 172®, Megaface F 173®, Megaface F 183®, etc. from Dainippon Ink Kagaku Kogyo; Fluorad FC-135®, Fluorad FC-170C®, Fluorad FC-430®, Fluorad FC-431®, etc. from Sumitomo 3M; Saffron S-112®, Saffron S-113®, Saffron S-131®, Saffron S-141®, Saffron S-145®, etc. from Asahi Glass; and SH-28PAR, SH-190®, SH-193®, SZ-6032®, SF-8428®, etc. from Toray Silicone.

The surfactant may be used in an amount of 0.001 to 5 parts by weight based on 100 parts by weight of the photosensitive resin composition. When the surfactant is contained within the above-described range, coating uniformity can be secured, stains do not occur, and wetting to the glass substrate is excellent.

As the crosslinker, 1,4-bis(methoxymethyl)benzene, diethyl sulfate, 3-aminopropyltriethoxysilane, N,N′-methylenebis acrylamide, etc. may be used, and these may be used alone or in a mixture of two or more.

The crosslinker may be used in an amount of 0.001 to 5 parts by weight per 100 parts by weight of the photosensitive resin composition. When the crosslinker is included within the above-described range, it is advantageous in appropriately imparting physical properties, for example, mechanical properties (e.g., tensile strength) to the cured coating film.

In addition, a certain amount of other additives may be added to the photosensitive resin composition within a range that does not impair physical properties. It is preferable that the additives are included in an amount of 0.001 wt % to 10 wt % based on the total amount of the composition.

Hereinafter, Synthesis Examples and Examples according to the present disclosure will be described in detail, but Synthesis Examples and Examples of the present disclosure are not limited thereto.

### Synthesis Example 1

A 250 mL three-neck round bottom flask was installed by attaching a stirrer, a nitrogen injection device, a dropping funnel, a temperature controller, and a cooler thereto, charged with 79.2 g of N-methylpyrrolidone (NMP) while filling it with nitrogen. Then, 15 g of 4,4′-cyclohexylidinebis[2-aminophenol] and 3.67 g of pyridine were added thereto and the mixture was maintained at 40° C. while stirring. 1.12 g of phthalic anhydride was slowly added thereto and the mixture was stirred for a certain period of time to allow dissolution and reaction to proceed. Thereafter, 110.742 g of NMP was added to the flask while the reaction was in progress, and the mixture was stirred for 30 minutes while maintaining the temperature of the solution at 5° C. Then,, 13.72 g of 4,4′-oxybisbenzoyl chloride was slowly added thereto and the mixture was stirred for 12 hours to allow dissolution and reaction to proceed.

The polyhydroxyamide solution was stirred at room temperature for 1 hour, precipitated with methanol, and the precipitated solid was dried under vacuum at 60° C. for 12 hours to obtain 26.86 g of copolymerized polyhydroxyamide powder.

### Synthesis Example 2

A 250 mL three-neck round bottom flask was installed by attaching a stirrer, a nitrogen injection device, a dropping funnel, a temperature controller, and a condenser thereto, charged with 79.2 g of N-methylpyrrolidone (NMP) while filling it with nitrogen. Then, 15 g of 4,4′-cyclohexylidinebis[benzeneamine] and 3.68 g of pyridine were added thereto and the mixture was maintained at 40° C. while stirring. 1.12 g of phthalic anhydride was slowly added thereto and the mixture was stirred for a certain period of time to allow dissolution and reaction to proceed. Thereafter, 80.67 g of NMP was added to the flask while the reaction was in progress, and the mixture was stirred for 30 minutes while maintaining the temperature of the solution at 5° C. Then, 8.417 g of 1,2-cyclobutanedicarboxylic acid dichloride was slowly added thereto and the mixture was stirred for 12 hours to allow dissolution and reaction to proceed.

The polyamic acid solution was stirred at room temperature for 1 hour, precipitated with methanol, and the precipitated solid was dried under vacuum at 60° C. for 12 hours to obtain 22.08 g of copolymerized polyamic acid powder.

### Synthesis Example 3

A 250 mL three-neck round bottom flask was installed by attaching a stirrer, a nitrogen injection device, a dropping funnel, a temperature controller, and a condenser thereto, charged with 79.2 g of N-methylpyrrolidone (NMP) while filling with nitrogen. Then, 15 g of 2,2-bis(3-amino-4-hydroxyphenyl)propane and 3.68 g of pyridine were added thereto and the mixture was maintained at 40° C. while stirring. 1.12 g of phthalic anhydride was slowly added thereto and the mixture was stirred for a certain period of time to allow dissolution and reaction to proceed. Thereafter, 88.06 g of NMP was added to the flask while the reaction was in progress, and the mixture was stirred for 30 minutes while maintaining the temperature of the solution at 5° C. Then, 9.72 g of 1,4-cyclohexanedicarboxylic acid dichloride was slowly added thereto and the mixture was stirred for 12 hours to allow dissolution and reaction to proceed.

The polyhydroxyamide solution was stirred at room temperature for 1 hour, precipitated with methanol, and the precipitated solid was dried under vacuum at 60° C. for 12 hours to obtain 23.25 g of copolymerized polyhydroxyamide powder.

### Synthesis Example 4

A 250 mL three-neck round bottom flask was installed by attaching a stirrer, a nitrogen injection device, a dropping funnel, a temperature controller, and a condenser thereto, charged with 79.18 g of N-methylpyrrolidone (NMP) while filling it with nitrogen. Then, 15 g of 4,4′-(1-methyleneethylidine)bis[benzeneamine] and 2.48 g of pyridine were added thereto and the mixture was maintained at 40° C. while stirring. 0.75 g of 5-norbornen-2,3-dicarboxylic anhydride was slowly added thereto and the mixture was stirred for a certain period of time to allow dissolution and reaction to proceed. Thereafter, 90.80 g of NMP was added to the flask while the reaction was in progress, and the mixture was stirred for 30 minutes while maintaining the temperature of the solution at 5° C. Then, 8.67 g of 1,4-cyclohexanedicarboxylic acid dichloride and bicyclo[2,2,2]octa-7-en-2,3,5,6-tetracarboxylic acid dihydride were slowly added thereto and the mixture was stirred for 12 hours to allow dissolution and reaction to proceed.

The polyamic acid solution was stirred at room temperature for 1 hour, precipitated with methanol, and the precipitated solid was dried under vacuum at 60° C. for 12 hours to obtain 20.75 g of copolymerized polyamic acid powder.

### Synthesis Example 5

A 250 mL three-neck round bottom flask was installed by attaching a stirrer, a nitrogen injection device, a dropping funnel, a temperature controller, and a condenser thereto, charged with 79.18 g of N-methylpyrrolidone (NMP) while filling it with nitrogen. Then, 15 g of 4,4-(bis(trimethylsilyl)methylene)bis(2-aminophenol) and 3.68 g of pyridine were added thereto and the mixture was maintained at 40° C. while stirring. 1.41 g of 5-norbornen-2,3-dicarboxylic anhydride was slowly added thereto and the mixture was stirred for a certain period of time to allow dissolution and reaction to proceed. Thereafter, 89.72 g of NMP was added to the flask while the reaction was in progress, and the mixture was stirred for 30 minutes while maintaining the temperature of the solution at 5° C. Then, 7.70 g of 1,4-cyclohexanedicarboxylic acid dichloride and 2.31 g of bicyclo[2,2,2]octa-7-en-2,3,5,6-tetracarboxylic acid dihydride were slowly added thereto and the mixture was stirred for 12 hours to allow dissolution and reaction to proceed.

The polyhydroxyamide solution was stirred at room temperature for 1 hour, precipitated with methanol, and the precipitated solid was dried under vacuum at 60° C. for 12 hours to obtain 20.75 g of copolymerized polyhydroxyamide powder.

### Synthesis Example 6

A 250 mL three-neck round bottom flask was installed by attaching a stirrer, a nitrogen injection device, a dropping funnel, a temperature controller, and a condenser thereto, charged with 79.18 g of N-methylpyrrolidone (NMP) while filling it with nitrogen. Then, 15 g of 4,4′-sulfonyldianiline and 2.94 g of pyridine were added thereto and the mixture was maintained at 40° C. while stirring. 0.72 g of bicyclo[2.2.2]octa-7-en-2,3-dicarboxylic anhydride was slowly added thereto and the mixture was stirred for a certain period of time to allow dissolution and reaction to proceed. Thereafter, 84.5 g of NMP was added to the flask while the reaction was in progress, and the mixture was stirred for 30 minutes while maintaining the temperature of the solution at 5° C. Then, 9.46 g of bicyclo[2,2,2]octa-7-en-2,3,5,6-tetracarboxylic acid dihydride were slowly added thereto and the mixture was stirred for 12 hours to allow dissolution and reaction to proceed.

The polyamic acid solution was stirred at room temperature for 1 hour, precipitated with methanol, and the precipitated solid was dried under vacuum at 60° C. for 12 hours to obtain 21.05 g of copolymerized polyamic acid powder.

### Synthesis Example 7

A 250 mL three-neck round bottom flask was installed by attaching a stirrer, a nitrogen injection device, a dropping funnel, a temperature controller, and a condenser thereto, charged with 79.18 g of N-methylpyrrolidone (NMP) while filling it with nitrogen. Then, 15 g of 4,4-bis(3-amino-4-hydroxyphenyl)heptane and 3.18 g of pyridine were added thereto and the mixture was maintained at 40° C. while stirring. 1.44 g of maleic anhydride was slowly added thereto and the mixture was stirred for a certain period of time to allow dissolution and reaction to proceed. Thereafter, 92.48 g of NMP was added to the flask while the reaction was in progress, and the mixture was stirred for 30 minutes while maintaining the temperature of the solution at 5° C. Then, 10.48 g of 1,4-cyclohexanedicarboxylic acid dichloride was slowly added thereto and the mixture was stirred for 12 hours to allow dissolution and reaction to proceed.

The polyhydroxyamide solution was stirred at room temperature for 1 hour, precipitated with methanol, and the precipitated solid was dried under vacuum at 60° C. for 12 hours to obtain 19.41 g of copolymerized polyhydroxyamide powder.

### Synthesis Example 8

A 250 mL three-neck round bottom flask was installed by attaching a stirrer, a nitrogen injection device, a dropping funnel, a temperature controller, and a condenser thereto, charged with 79.18 g of N-methylpyrrolidone (NMP) while filling it with nitrogen. Then, 15 g of 4-amino-N-(4-aminophenyl)benzoamide and 2.87 g of pyridine were added thereto and the mixture was maintained at 40° C. while stirring. 1.48 g of maleic anhydride was slowly added thereto and the mixture was stirred for a certain period of time to allow dissolution and reaction to proceed. Thereafter, 91.42 g of NMP was added to the flask while the reaction was in progress, and the mixture was stirred for 30 minutes while maintaining the temperature of the solution at 5° C. Then, 10.62 g of bicyclo[2,2,2]octa-7-en-2,3,5,6-tetracarboxylic acid dihydride was slowly added thereto and the mixture was stirred for 12 hours to allow dissolution and reaction to proceed.

The polyamic acid solution was stirred at room temperature for 1 hour, precipitated with methanol, and the precipitated solid was dried under vacuum at 60° C. for 12 hours to obtain 22.15 g of copolymerized polyamic acid powder.

### Synthesis Example 9

A 250 mL three-neck round bottom flask was installed by attaching a stirrer, a nitrogen injection device, a dropping funnel, a temperature controller, and a condenser thereto, charged with 79.18 g of N-methylpyrrolidone (NMP) while filling it with nitrogen. Then, 15 g of bis(3-amino-4-hydroxyphenyl) sulfone and 4.84 g of pyridine were added thereto and the mixture was maintained at 40° C. while stirring. 2.84 g of bicyclo[2,2,2]octa-7-en-2,3,5,6-tetracarboxylic acid dihydride was slowly added thereto and the mixture was stirred for a certain period of time to allow dissolution and reaction to proceed. Thereafter, 91.58 g of NMP was added to the flask while the reaction was in progress, and the mixture was stirred for 30 minutes while maintaining the temperature of the solution at 5° C. Then, 13.93 g of bicyclo[2,2,2]octa-7-en-2,3,5,6-tetracarboxylic acid dihydride was slowly added thereto and the mixture was stirred for 12 hours to allow dissolution and reaction to proceed.

The polyhydroxyamide solution was stirred at room temperature for 1 hour, precipitated with methanol, and the precipitated solid was dried under vacuum at 60° C. for 12 hours to obtain 23.82 g of copolymerized polyhydroxyamide powder.

### Synthesis Example 10

A 250 mL three-neck round bottom flask was installed by attaching a stirrer, a nitrogen injection device, a dropping funnel, a temperature controller, and a condenser thereto, charged with 79.18 g of N-methylpyrrolidone (NMP) while filling it with nitrogen. Then, 15 g of 4,4′-diaminodiphenyl sulfide and 4.12 g of pyridine were added thereto and the mixture was maintained at 40° C. while stirring. 3.84 g of bicyclo[2,2,2]octa-7-en-2,3,5,6-tetracarboxylic acid dihydride was slowly added thereto and the mixture was stirred for a certain period of time to allow dissolution and reaction to proceed. Thereafter, 95.62 g of NMP was added to the flask while the reaction was in progress, and the mixture was stirred for 30 minutes while maintaining the temperature of the solution at 5° C. Then, 9.98 g of 4,4′-benzophenonetetracarboxylic acid dianhydride was slowly added thereto and the mixture was stirred for 12 hours to allow dissolution and reaction to proceed.

The polyamic acid solution was stirred at room temperature for 1 hour, precipitated with methanol, and the precipitated solid was dried under vacuum at 60° C. for 12 hours to obtain 21.05 g of copolymerized polyamic acid powder.

### Synthesis Example 11

A 250 mL three-neck round bottom flask was installed by attaching a stirrer, a nitrogen injection device, a dropping funnel, a temperature controller, and a condenser thereto, charged with 79.18 g of N-methylpyrrolidone (NMP) while filling it with nitrogen. Then, 15 g of 4,4′-oxybis[2-aminophenol] and 3.66 g of pyridine were added thereto and the mixture was maintained at 40° C. while stirring. 1.12 g of phthalic anhydride was slowly added thereto and the mixture was stirred for a certain period of time to allow dissolution and reaction to proceed. Thereafter, 87.52 g of NMP was added to the flask while the reaction was in progress, and the mixture was stirred for 30 minutes while maintaining the temperature of the solution at 5° C. Then, 13.25 g of 1,4-cyclohexanedicarboxylic acid dichloride was slowly added thereto and the mixture was stirred for 12 hours to allow dissolution and reaction to proceed.

The polyhydroxyamide solution was stirred at room temperature for 1 hour, precipitated with methanol, and the precipitated solid was dried under vacuum at 60° C. for 12 hours to obtain 20.11 g of copolymerized polyhydroxyamide powder.

### Synthesis Example 12

A 250 mL three-neck round bottom flask was installed by attaching a stirrer, a nitrogen injection device, a dropping funnel, a temperature controller, and a condenser thereto, charged with 65.7 g of N-methylpyrrolidone (NMP) while filling it with nitrogen. Then, 15 g of 2,2-bis(3-amino-4-hydroxyphenyl)hexafluoropropane and 0.52 g of pyridine were added thereto and the mixture was maintained at 40° C. while stirring. 0.910 g of phthalic anhydride was slowly added thereto and the mixture was stirred for a certain period of time to allow dissolution and reaction to proceed. Thereafter, 52.70 g of NMP was added to the flask while the reaction was in progress, and the mixture was stirred for 30 minutes while maintaining the temperature of the solution at 5° C. Then, 11.18 g of 4,4′-oxybisbenzoyl chloride was slowly added thereto and the mixture was stirred for 12 hours to allow dissolution and reaction to proceed.

The polyhydroxyamide solution was stirred at room temperature for 1 hour, precipitated with methanol, and the precipitated solid was dried under vacuum at 60° C. for 12 hours to obtain 21.13 g of copolymerized polyhydroxyamide powder.

### Preparation Example 1

### Preparation of Positive Photosensitive Resin Composition

14.881 g of a benzoxazole copolymer resin obtained in Synthesis Examples 1 to 7, 2.232 g of MIPHOTO TPD523 (Miwon Specialty Chemical), 0.004 g of F-563 (DIC Corporation), 0.223 g of KBM-573 (Shinetsu Silicone), and 0.149 g of 1,4-bis(methoxymethyl)benzene were stirred at room temperature together with 32.5 g of gamma-butyrolactone for 12 hours. Then, the photosensitive resin composition was prepared by filtering the composition three times to remove impurities.

The photosensitive resin composition was prepared according to the compositions shown in Table 1 below.

TABLE 1

| | | MIPHOTO | | | 1,4- | Gamma- |
|---|---|---|---|---|---|---|
| | | TPD523 | F-563 | KBM-573 | Bis(methoxymethyl)benzene | butyrolactone |
| | Copolymer | (%) | (%) | (%) | (%) | (%) |
| Example 1 | Synthesis | 4.47 | 0.01 | 0.45 | 0.30 | 65.0 |
| | Example 1 | | | | | |
| | 29.77% | | | | | |
| Example 2 | Synthesis | 4.47 | 0.01 | 0.45 | 0.30 | 65.0 |
| | Example 2 | | | | | |
| | 29.77% | | | | | |
| Example 3 | Synthesis | 4.47 | 0.01 | 0.45 | 0.30 | 65.0 |
| | Example 3 | | | | | |
| | 29.77% | | | | | |
| Example 4 | Synthesis | 4.47 | 0.01 | 0.45 | 0.30 | 65.0 |
| | Example 4 | | | | | |
| | 29.77% | | | | | |
| Example 5 | Synthesis | 4.47 | 0.01 | 0.45 | 0.30 | 65.0 |
| | Example 5 | | | | | |
| | 29.77% | | | | | |
| Example 6 | Synthesis | 4.47 | 0.01 | 0.45 | 0.30 | 65.0 |
| | Example 6 | | | | | |
| | 29.77% | | | | | |
| Example 7 | Synthesis | 4.47 | 0.01 | 0.45 | 0.30 | 65.0 |
| | Example 7 | | | | | |
| | 29.77% | | | | | |
| Example 8 | Synthesis | 4.47 | 0.01 | 0.45 | 0.30 | 65.0 |
| | Example 8 | | | | | |
| | 29.77% | | | | | |
| Example 9 | Synthesis | 4.47 | 0.01 | 0.45 | 0.30 | 65.0 |
| | Example 9 | | | | | |
| | 29.77% | | | | | |
| Example 10 | Synthesis | 4.47 | 0.01 | 0.45 | 0.30 | 65.0 |
| | Example 10 | | | | | |
| | 29.77% | | | | | |
| Example 11 | Synthesis | 4.47 | 0.01 | 0.45 | 0.30 | 65.0 |
| | Example 11 | | | | | |
| | 29.77% | | | | | |
| Comparative | Synthesis | 4.47 | 0.01 | 0.45 | 0.30 | 65.0 |
| Example 1 | Example 7 | | | | | |
| | 29.77% | | | | | |

The process of forming a cured film on a silicon wafer using the positive photosensitive resin composition is as follows.

### (1) Application and Coating Steps

The photosensitive resin compositions prepared in Examples or Comparative Examples are each applied onto a washed 200 mm silicon wafer at a predetermined thickness using a spin coater, and then a portion of the solvent is removed using vacuum chamber dry (VCD) to form a coating film. The photosensitive resin compositions each form a film to have a coating thickness of 5 μm to 10 μm after VCD.

### (2) Prebaking Step

In order to remove the solvent contained in the obtained coating film, the film is heated on a hot plate at 100° C. to 140° C. for 50 seconds to 200 seconds. By removing a certain amount of the solvent in the corresponding process, a coating film with a certain thickness may also be obtained in the development step after the next process (exposure).

### (3) Exposure Step

In order to obtain a constant thickness required for the obtained coating film, a pattern may be formed by irradiating an active ray of 190 nm to 600 nm in an exposure machine, preferably a light source of a metal or LED lamp having a ghi-line. The exposure dose of irradiation is 50 mJ/cm² to 500 mJ/cm², and the pattern being formed is a positive type Holes and Lines and Space patterns per size in um unit.

### (4) Development Step

Following the exposure step, the film is developed by the puddle method of dipping the coating film in tetramethylammonium hydroxide (TMAH) as a developer at 23±2° C. for a certain period of time (minutes), and washed using ultrapure water (DI water). As a result, the non-exposed portion is dissolved and removed so that only the exposed portion remains to form an image pattern, and the thickness of the coating film is 4.0 μm to 9.0 μm.

### (5) Post-Baking Step

In order to obtain the image pattern obtained by the development, the obtained coating film is cured by performing post-baking in an oven at 300° C. to 320° C. for 30 to 120 minutes.

### (6) FE-SEM Measurement

Sampling was performed on the substrate after the post-baking treatment step without damaging the pattern, and thereby Hole, Line, and Space patterns were observed using JSM-IT800, which is a scanning electron microscope of JEOL.

TABLE 2

| | | Hole | |
|---|---|---|---|
| | Residue After | Pattern Accuracy (10 | Resolution |
| | Development* | μm) | (μm) |
| Example 1 | X | 9.9576 | 3 |
| Example 2 | X | 9.9742 | 3 |
| Example 3 | X | 9.9365 | 2 |
| Example 4 | X | 9.9554 | 3 |
| Example 5 | X | 9.9778 | 3 |
| Example 6 | X | 10.0325 | 2 |
| Example 7 | X | 9.9485 | 3 |
| Example 8 | X | 9.9352 | 2 |
| Example 9 | X | 9.9482 | 3 |
| Example 10 | X | 9.9768 | 3 |
| Example 11 | X | 9.9876 | 3 |
| Comparative | Δ | 9.9334 | 3 |
| Example 1 | | | |

*X—no residue, Δ—presence of residue, ◯—many residues

After performing the development process and post-baking treatment disclosed in Table 2 above, Hole, Line, and Space patterns were observed using a scanning electron microscope. It was confirmed in Examples 1 to 11 that no residue remained after development. In contrast, it was confirmed in Comparative Example 1 that a small amount of residue remained in a lower part of the Hole pattern.

In addition, as a result of confirming the accuracy of the Hole implementation by observing the implementation of a 10 μm Hole pattern, it was confirmed the pattern was accurately implemented with an error of less than 0.1 μm for all of Examples 1 to 11 and Comparative Example 1. It was confirmed that the minimum resolution implemented in both Example 1 to Example 11 and Comparative Example 1 was 2 μm to 3 μm.

According to the test results of the present disclosure, it was confirmed that by using a polyimide precursor and a polybenzoxazole precursor that do not contain fluorine, the performance was shown to be similar to those of existing fluorine-based materials, and much improved results were shown in terms of residue after development.

The present disclosure is not limited to the Examples above but may be prepared in various different forms.

The above description is merely illustrative of the present disclosure, and those skilled in the art to which the present disclosure pertains will be able to make various modifications without departing from the essential characteristics of the present disclosure.

Accordingly, the embodiments disclosed in this specification are for illustrative purposes only and are not intended to limit the present disclosure, and the spirit and scope of the present disclosure are not limited by these embodiments. The scope of protection of the present disclosure should be interpreted in accordance with the claims, and all technologies within the scope equivalent thereto should be interpreted as being included in the scope of rights of the present disclosure.

What is claimed is:

1. A benzoxazole copolymer comprising a repeating unit selected from the group consisting of the following Formulas 1-1 and 1-2, and a combination thereof: 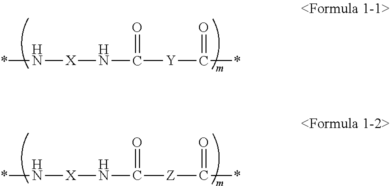
wherein in Formulas 1-1 and Formula 1-2 above,
1) * represents a part where a bond is connected by a repeating unit,
2) X is Formula 2 below: 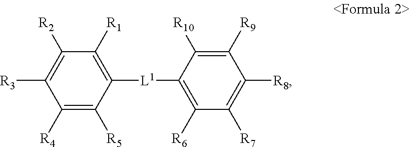
3) two of R¹ to R¹⁰ are connection parts with an amide group of Formula 1-1 or Formula 1-2 above,
4) the remaining ones of R¹ to R¹⁰ excluding the connection parts are each independently selected from the group consisting of hydrogen; deuterium; a hydroxy group; a C₆₋₃₀ aryl group; a C₂₋₃₀ heterocyclic group comprising at least one heteroatom among O, N, S, Si, and P; a fused ring group of a C₆₋₃₀ aliphatic ring and a C₆₋₃₀ aromatic ring; a C₁-C₂₀ alkyl group; a C₂-C₂₀ alkenyl group; a C₂-C₂₀ alkynyl group; a C₁-C₂₀ alkoxy group; a C₆-C₃₀ aryloxy group; a fluorenyl group; a carbonyl group; an ether group; a carboxyl group; a C₁-₂₀ alkoxycarbonyl group; and a combination thereof,
5) L¹ is selected from the group consisting of a single bond; a C₆-₃₀ arylene group; a C₂₋₃₀ heterocyclic group comprising at least one heteroatom among O, N, S, Si, and P; a fused ring group of a C₆₋₃₀ aliphatic ring and a C₆₋₃₀ aromatic ring; a C₁-₂₀ alkylene group; a C₃₋₂₀ cycloalkylene group; a C₂-₂₀ alkenylene group; a C₃₋₂₀ cycloalkenylene group; a C₂₋₂₀ alknylene group; a C₃₋₂₀ cycloalkynylene group; and —O—, —S—, —SO₂—, Si(CH₃)₂—, —C(SiCH₃)₂, —C₆H₄—, —CO—, —NHCO—, and —COO—,
6) when L¹ is a single bond, neighboring R₁ and R₁₀; and R₅ and R₆, which are not the connection parts, can form a ring,
7) Y and Z are each independently selected from the group consisting of a C₆-₃₀ arylene group; a C₂₋₃₀ heterocyclic group comprising at least one heteroatom among O, N, S, Si, and P; a fused ring group of a C₆₋₃₀ aliphatic ring and a C₆₋₃₀ aromatic ring; a C₁-₂₀ alkylene group; a C₃₋₂₀ cycloalkylene group; a C₂-₂₀ alkenylene group; a C₃₋₂₀ cycloalkenylene group; a C₂₋₂₀ alknylene group; a C₃₋₂₀ cycloalkynylene group; and a combination thereof,
8) in Y or Z, each independently, at least one carboxylic acid group; or an ester group having an end of C₁-₂₀ can be additionally substituted,
9) m or n is an integer of 1 or more, and
10) the polymer end is connected by one selected from Formulas Q-1 to Q-10 below:

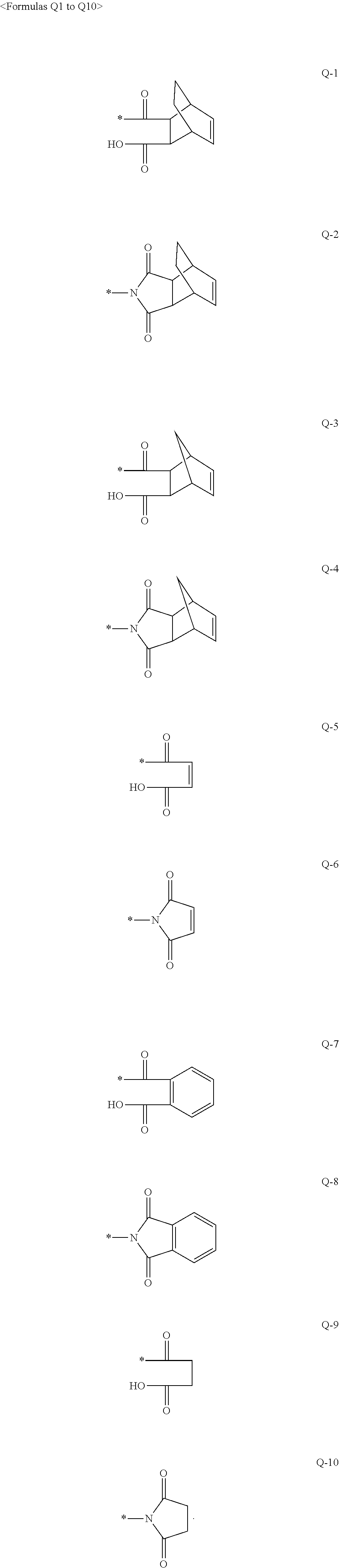

2. The benzoxazole copolymer of claim 1, wherein Formula 2 is a benzoxazole copolymer represented by A-1 to A-15 below: 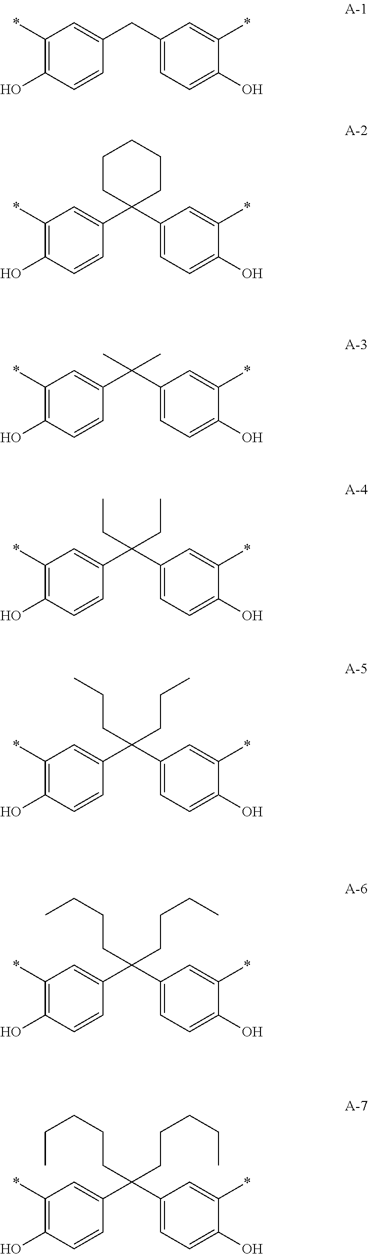 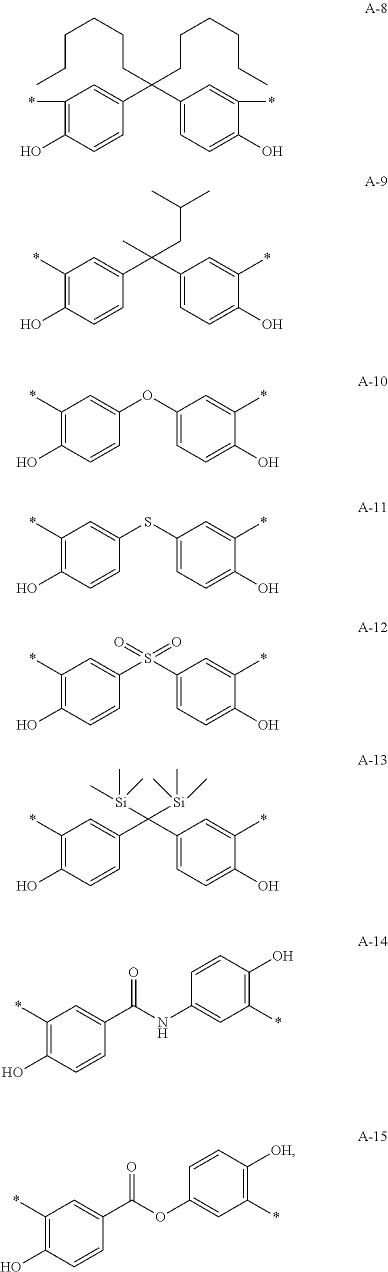
wherein in A-1 to A-15 above, * represents a connection part with an amide group of Formula 1-1 or Formula 1-2 above.

3. The benzoxazole copolymer of claim 1, wherein Formula 2 above is an imide copolymer represented by B-I to B-15 below: 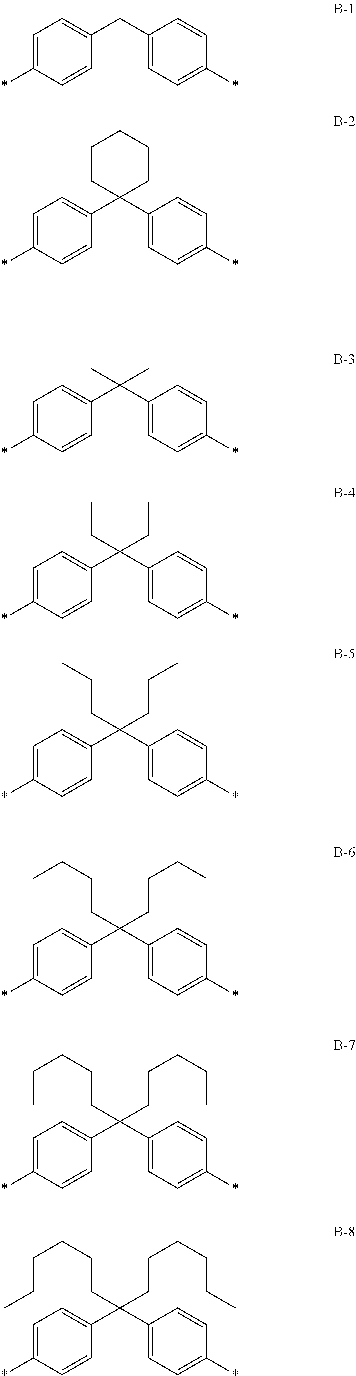 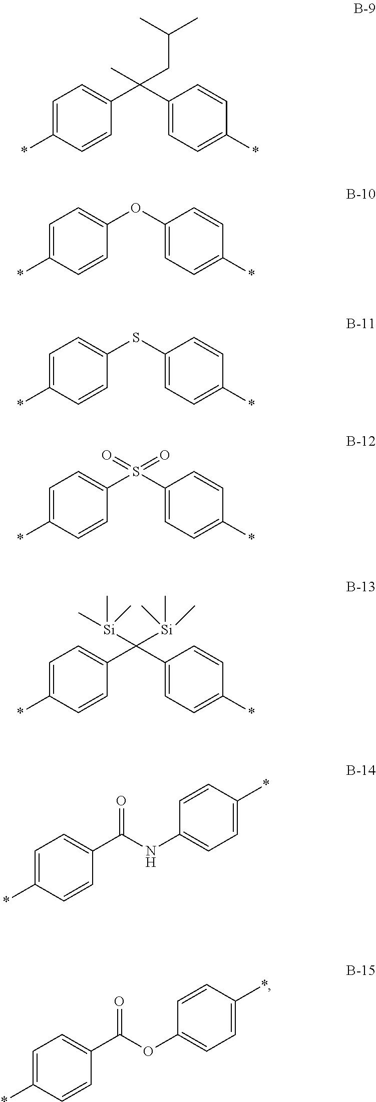
wherein in B-1 to B-15 above, * represents a connection part with an amide group of Formula 1-1 or Formula 1-2 above.

4. The benzoxazole copolymer of claim 1, wherein the copolymer is prepared from a diamine monomer; a diacyl chloride monomer; a dianhydride monomer; and an anhydride monomer.

5. The benzoxazole copolymer of claim 4, wherein the diamine comprises at least one monomer selected from the group consisting of 4,4′-methylenebis[2-aminophenol], 2,2-bis(3-amino-4-hydroxyphenyl)propane, 3,3-bis(3-amino-4-hydroxyphenyl)pentane, 4,4-bis(3-amino-4-hydroxyphenyl)heptane, 5,5-bis(3-amino-4-hydroxyphenyl)nonane, 6,6-bis(3-amino-4-hydroxyphenyl)dodecane, 7,7-bis(3-amino-4-hydroxyphenyl)tridecane, 4,4′-cyclohexylidinebis[2-aminophenol] 4,4′-(1,3-dimethylbutylidine)bis[2-aminophenol], 4,4′-oxybis[2-aminophenol], 4,4′-thiobis[2-aminophenol], bis(3-amino-4-hydroxyphenyl)sulfone, 4,4′-(bis(trimethylsilyl)methylene)bis(2-aminophenol), 4-hydroxy-N-(4-hydroxy-3λ³-phenyl)3-λ³benzamide, 4,4-diaminodiphenylmethane, 4,4′-(1-methyleneethylidine)bis[benzeneamine], 4,4′-(1-ethylpropylidine)bis[benzeneamine], 4,4′-(1-propylbutyridine)bis[benzeneamine], 4,4′-(1-butylpentylidene)bis[benzeneamine], 4,4′-(1-pentylhexylidine)bis[benzeneamine], 4,4′-(hexylheptylidine)bis[benzeneamine], 4,4′-cyclohexylidinebis[benzeneamine], 4,4′-(1,3-dimethylbutylidine)bis[benzeneamine], 4,4′-diaminodiphenyl ether, 4,4′-diaminodiphenyl sulfide, 4,4′-sulfonyldianiline, 4,4′-(bis(trimethylsilyl)methylidine)dianiline, 4-amino-N-(4-aminophenyl)benzoamide, 4-aminophenyl 4-aminobenzoate, and a combination thereof.

6. The benzoxazole copolymer of claim 4, wherein the diacylchloride comprises at least one monomer selected from the group consisting of 4,4′-oxybisbenzoyl chloride, 1,2-cyclobutanedicarboxylic acid dichloride, terephthaloyl chloride, isophthaloyl chloride, 4,4′-biphenyldicarbonyl chloride, 1,4-naphthalenedicarbonyl chloride, 4,4′-sulfonyldibenzoyl chloride, 1,4-cyclohexanedicarboxylic acid dichloride, and a combination thereof.

7. The benzoxazole copolymer of claim 4, wherein the dianhydride comprises at least one monomer selected from the group consisting of 4,4-oxydiphthalic anhydride, 3,3′,4,4′-biphenyltetracarboxylic dianhydride, 2,3,3′4′-biphenyltetracarboxylic acid dianhydride, bicyclo[2,2,2]octa-7-en-2,3,5,6-tetracarboxylic acid dianhydride, 4,4′-(hexafluoroisopropylidine)diphthalic anhydride, bicyclo[2,2,2]octan-2,3,5,6-tetracarboxylic dianhydride, 3,3′,4,4′-benzophenonetetracarboxylic acid dianhydride, 1,2,3,4-butanetetracarboxylic acid dianhydride, cyclobutan-1,2,3,4-tetracarboxylic acid dianhydride, cyclocyclohexan-1,2,4,5-tetracarboxylic acid dianhydride, dicyclohexyl-3,4,3′4′-tetracarboxylic acid dianhydride, 1,4,5,8-naphthalenetetracarboxylic acid dianhydride, and a combination thereof.

8. The benzoxazole copolymer of claim 4, wherein the anhydride comprises at least one monomer selected from the group consisting of bicyclo[2.2.2]octa-5-en-2,3-dicarboxylic anhydride, 5-norbornen-2,3-dicarboxylic anhydride, maleic anhydride, phthalic anhydride, succinic anhydride, and a combination thereof.

9. The benzoxazole copolymer of claim 1, wherein the weight average molecular weight of the copolymer is 5,000 g/mol to 40,000 g/mol.

10. A positive photosensitive resin composition comprising the benzoxazole copolymer of claim 1; a photoactive compound; a solvent; and an additive.

11. The positive photosensitive resin composition of claim 10, wherein the photoactive compound comprises at least one of Formulas P-1 to P-8 below: 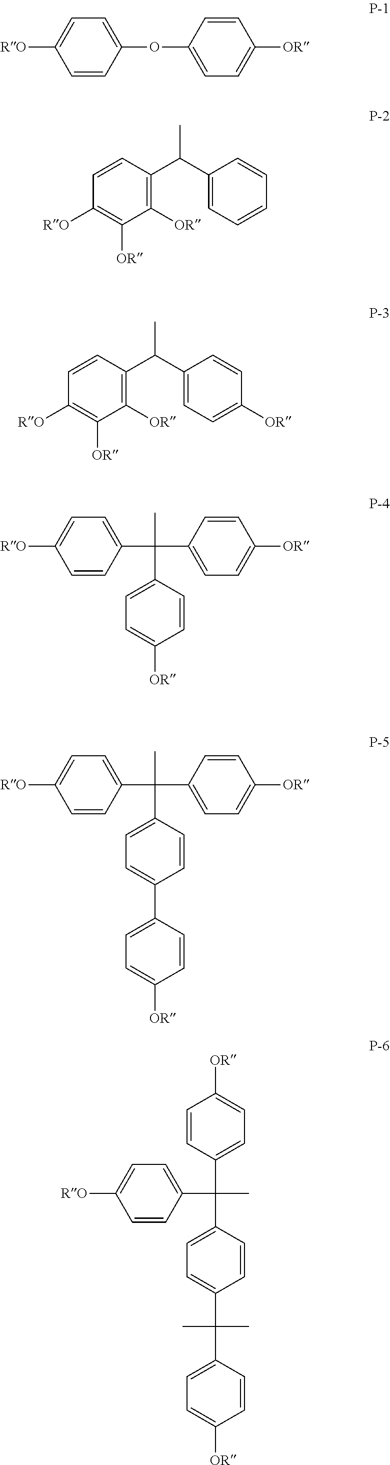 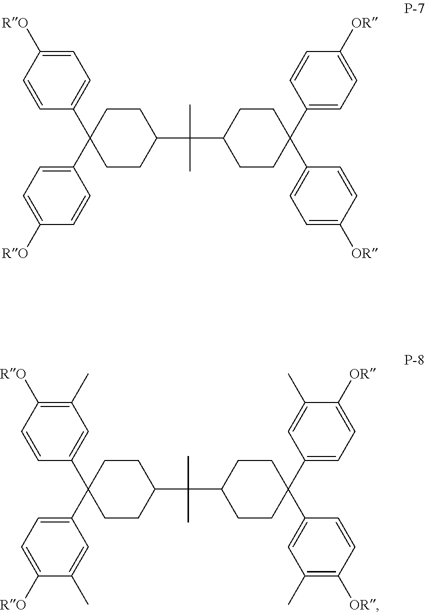
wherein in P-1 to P-8 above, R″s are each independently hydrogen; Formula S-1 below; or Formula S-2 below:

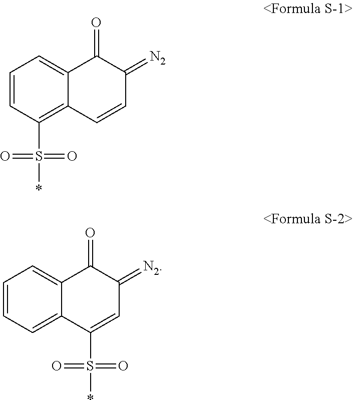

12. The positive photosensitive resin composition of claim 10, wherein the solvent comprises at least one selected from the group consisting of N,N-dimethylformamide, N-methylformanilide, N-methylacetamide, N,N-dimethylacetamide, N-methylpyrrolidone, dimethyl sulfoxide, benzyl ethyl ether, dihexyl ether, acetyl acetone, gamma-butyrolactone, diethylene glycol monomethyl ether, diethylene glycol monoethyl ether, diethylene glycol dimethyl ether, diethylene glycol methyl ethyl ether, diethylene glycol diethyl ether, propylene glycol methyl ether acetate, propylene glycol propyl ether acetate, and a combination thereof.

13. The positive photosensitive resin composition of claim 10, wherein the additive comprises at least one selected from the group consisting of a silane-based coupling agent; a surface leveling agent; a surfactant; a crosslinking agent; and a combination thereof.

14. The positive photosensitive resin composition of claim 10, wherein the benzoxazole copolymer is contained in an amount of 5 wt % to 50 wt % based on the total amount of the composition.

15. The positive photosensitive resin composition of claim 10, wherein the photoactive compound is contained in an amount of 1 wt % to 50 wt % based on the total amount of the composition.

16. The positive photosensitive resin composition of claim 10, wherein the solvent is contained in an amount of 50 wt % to 95 wt % based on the total amount of the composition.

17. The positive photosensitive resin composition of claim 10, wherein the additive is contained in an amount of 0.001 wt % to 10 wt % based on the total amount of the composition.

18. A pattern or film prepared from the positive photosensitive resin composition of claim 10.

19. A semiconductor device prepared using the pattern or film of claim 18.

20. A display device prepared using the pattern or film of claim 18.
